(19) United States
(12) Patent Application Publication
(10) Pub. No.: US 2026/0293386 A1
(43) Pub. Date: Sep. 24, 2026

(54) DISPLAY DEVICE, MANUFACTURING METHOD OF THE SAME AND ELECTRONIC DEVICE

(71) Applicant: Samsung Display Co., Ltd., Yongin-si (KR)

(72) Inventors: Jae Gwang UM, Yongin-si (KR); Tae Hee LEE, Yongin-si (KR); Moon Won CHANG, Yongin-si (KR); Ki Su JIN, Yongin-si (KR)

(21) Appl. No.: 19/394,554

(22) Filed: Nov. 19, 2025

(30) Foreign Application Priority Data
Mar. 19, 2025 (KR) 10-2025-0035205

(51) Int. Cl. H10H 20/857; H10H 20/01; H10H 20/819; H10H 20/824; H10H 20/825; H10H 20/84

(52) U.S. Cl. CPC H10H 20/857; H10H 20/0364; H10H 20/819; H10H 20/824; H10H 20/825; H10H 20/84

(57) ABSTRACT

A display device includes: a substrate including first light emitting areas and second light emitting areas; first pixel electrodes arranged in the first light emitting areas on the substrate, and second pixel electrodes arranged in the second light emitting areas on the substrate; first light emitting elements arranged in the first pixel electrodes and configured to emit light of a first wavelength, and second light emitting elements arranged in the second pixel electrodes and configured to emit light of a second wavelength, wherein the second wavelength is a different wavelength than the first wavelength; and bonding organic pads respectively arranged between the first pixel electrodes and the first light emitting elements corresponding to the first pixel electrodes, and bottom bonding electrodes respectively arranged between the second pixel electrodes and the second light emitting elements corresponding to the second pixel electrodes.

### CROSS-REFERENCE TO RELATED APPLICATION

This application claims priority to and the benefit of Korean Patent Application No. 10-2025-0035205, filed on Mar. 19, 2025, in the Korean Intellectual Property Office, the entire disclosure of which is incorporated by reference herein.

### BACKGROUND

### 1. Field

The present disclosure relates to a display device, a method of manufacturing the same, and an electronic device.

### 2. Description of the Related Art

As the information society develops, the demand for display devices for displaying images is increasing in various forms. The display device may be a flat panel display device such as a liquid crystal display, a field emission display, a light emitting display, and/or the like.

The light emitting display device may include an organic light emitting display device including an organic light emitting diode (OLED) element as a light emitting element, and an ultra-small light emitting display device including a micro light emitting diode element (hereinafter referred to as a micro light emitting element) as a light emitting element. Because the micro light emitting diode element is made of an inorganic material, it has the advantage of having a long lifespan due to less deterioration issues compared to an organic light emitting diode (OLED) element.

The manufacturing process of a light-emitting display device requires a process for bonding ultra-small light-emitting diode elements to a panel.

### SUMMARY

Aspects and features of embodiments of the present disclosure are to provide a display device, a method of manufacturing the same, and an electronic device capable of compensating for a step difference of a plurality of light emitting elements having a step difference in a display panel.

However, the present disclosure is not limited to those set forth herein. The above and other embodiments of the present disclosure will become more apparent to one of ordinary skill in the art to which the present disclosure pertains by referencing the detailed description of the present disclosure given below.

According to one or more embodiments of the present disclosure, a display device comprising: a substrate including first light emitting areas and second light emitting areas; first pixel electrodes arranged in the first light emitting areas on the substrate, and second pixel electrodes arranged in the second light emitting areas on the substrate; first light emitting elements arranged in the first pixel electrodes and configured to emit light of a first wavelength, and second light emitting elements arranged in the second pixel electrodes and configured to emit light of a second wavelength, wherein the second wavelength is a different wavelength than the first wavelength; and bonding organic pads respectively arranged between the first pixel electrodes and the first light emitting elements corresponding to the first pixel electrodes, and bottom bonding electrodes respectively arranged between the second pixel electrodes and the second light emitting elements corresponding to the second pixel electrodes, wherein the bonding organic pads and the bottom bonding electrodes comprise different materials, wherein heights of the first light emitting elements are different from heights of the second light emitting elements, wherein a distance from an interface of the first pixel electrode and the bonding organic pad to a top surface of the first light emitting element is the same as a distance from an interface of the second pixel electrode and the bottom bonding electrode to a top surface of the second light emitting element.

According to one or more embodiments, the display device further comprising: a bonding metal pad arranged between the bonding organic pad and the first light emitting element, and an upper bonding electrode arranged between the bottom bonding electrode and the second light emitting element.

According to one or more embodiments, the bonding organic pad comprises an organic material, wherein the bottom bonding electrode comprises a metal material.

According to one or more embodiments, the bonding organic pad comprises a polymer resin and conductive nanoparticles dispersed in the polymer resin.

According to one or more embodiments, the conductive nanoparticles comprise conductive carbon black.

According to one or more embodiments, the bonding metal pad and the upper bonding electrode comprise different metals.

According to one or more embodiments, the bonding metal pad comprises a metal having higher conductivity than the upper bonding electrode.

According to one or more embodiments, a distance from one side of the bonding organic pad to an other side of the bonding organic pad is shorter than a distance from one side of the bottom bonding electrode to an other side of the bottom bonding electrode, and wherein a distance from one side of the first light emitting element to an other side of the first light emitting element is longer than a distance from one side of the second light emitting element to an other side of the second light emitting element.

According to one or more embodiments, the distance from the one side of the bonding organic pad to the other side of the bonding organic pad is 1 μm or less.

According to one or more embodiments, the first light emitting elements comprise a gallium arsenide (GaAs) based inorganic material, and the second light emitting elements comprise a gallium nitride (GaN) based material.

According to one or more embodiments, the first light emitting elements comprise a flat upper portion, and the second light emitting elements comprise an upper portion having a concave structure having a cross-sectional shape of a semicircle or a semiellipse.

According to one or more embodiments, the first light emitting elements comprise an upper portion having a first concave structure having a cross-sectional shape of a semicircle or a semiellipse, and wherein the second light emitting elements comprise an upper portion having a second concave structure having a cross-sectional shape of a semicircle or a semiellipse.

According to one or more embodiments, the first concave structure has a relatively smaller height difference than the second concave structure.

According to one or more embodiments, each of the first light emitting element and the second light emitting element comprises: a first semiconductor layer doped with a first conductive dopant; a second semiconductor layer doped with a second conductive dopant; an active layer arranged between the first semiconductor layer and the second semiconductor layer; a protective film arranged on side surfaces of the first semiconductor layer, the active layer, and the second semiconductor layer; and a contact electrode arranged on a bottom surface of the first semiconductor layer.

According to one or more embodiments, the bonding organic pads comprise a non-conductive organic material and the first light emitting element further comprises a connection electrode arranged on the first pixel electrode and electrically connecting the first light emitting element.

According to one or more embodiments, a method for manufacturing a display device comprising: forming first pixel electrodes in a first light emitting area on a substrate, and second pixel electrodes in a second light emitting area on the substrate; forming bonding organic pads on the first pixel electrodes and bottom bonding electrodes on the second pixel electrodes using different materials; arranging first light emitting elements configured to emit light of a first wavelength and have a bonding metal pad arranged on one surface of the first light emitting elements on the bonding organic pads, and arranging second light emitting elements configured to emit light of a second wavelength and have an upper bonding electrode arranged on one surface of the second light emitting elements on the bottom bonding electrode, wherein the second wavelength is a different wavelength from the first wavelength, and heights of the first light emitting elements are different from heights of the second light emitting elements; and applying pressure from above the first light emitting elements and the second light emitting elements, and applying heat to the bonding organic pads and the bottom bonding electrode to bond the first light emitting elements and the second light emitting elements to the first pixel electrodes and the second pixel electrodes, wherein a distance from an interface of the first pixel electrode and the bonding organic pad after the pressure to a top surface of the first light emitting element is the same as a distance from an interface of the second pixel electrode and the bottom bonding electrode to a top surface of the second light emitting element.

According to one or more embodiments, based on the applying the pressure from above the first light emitting elements and the second light emitting elements, the bonding metal pad is sunk into the bonding organic pad and fixed by adhesion.

According to one or more embodiments, the bonding organic pad comprises a polymer resin and conductive nanoparticles dispersed in the polymer resin, and wherein the bottom bonding electrode comprises a metal material.

According to one or more embodiments, an electronic device comprising: a display panel; a window arranged on the display panel; and a bottom cover arranged below the display panel, wherein the display panel comprising, a substrate including first light emitting areas and second light emitting areas; first pixel electrodes arranged in the first light emitting areas on the substrate, and second pixel electrodes arranged in the second light emitting areas on the substrate; first light emitting elements arranged in the first pixel electrodes and configured to emit light of a first wavelength, and second light emitting elements arranged in the second pixel electrodes and configured to emit light of a second wavelength, wherein the second wavelength is a different wavelength than the first wavelength; and bonding organic pads respectively arranged between the first pixel electrodes and the first light emitting elements corresponding to the first pixel electrodes, and bottom bonding electrodes respectively arranged between the second pixel electrodes and the second light emitting elements corresponding to the second pixel electrodes, wherein the bonding organic pads and the bottom bonding electrodes comprise different materials, wherein heights of the first light emitting elements are different from heights of the second light emitting elements, wherein a distance from an interface of the first pixel electrode and the bonding organic pad to a top surface of the first light emitting element is the same as a distance from an interface of the second pixel electrode and the bottom bonding electrode to a top surface of the second light emitting element.

According to one or more embodiments, the electronic device further comprising: a battery arranged in a space of the bottom cover and configured to supply power to the display panel; and a middle frame arranged between the window and the bottom cover.

According to the display device and its manufacturing method according to one or more embodiments, bonding defects may be reduced or minimized even when there is a step difference between light emitting elements.

The reduction of bonding defects may be desirable in terms of cost.

Panel image quality and defects may be improved due to reduced bonding defects.

However, the effects, aspects, and features of the present disclosure are not limited to the aforementioned effects, aspects, and features, and various other effects, aspects, and features are included in the present specification.

### BRIEF DESCRIPTION OF THE DRAWINGS

FIG. 1 is a perspective view illustrating a display device according to one or more embodiments.

FIG. 2 is a layout diagram illustrating a display device according to one or more embodiments.

FIG. 3 is a block diagram illustrating a display device according to one or more embodiments.

FIG. 4 is an equivalent circuit diagram illustrating a sub-pixel according to one or more embodiments.

FIG. 5 is a layout diagram illustrating pixels of a display area according to one or more embodiments.

FIG. 6 is a cross-sectional view illustrating an example cross-section of one display panel corresponding to the lines I1-I1' in FIG. 5.

FIG. 7 is a cross-sectional view illustrating an example of an area A in FIG. 6 in detail.

FIG. 8 is a cross-sectional view illustrating in detail one example of the bonding structure of the first pixel electrode and the first light emitting element of FIG. 6 and the bonding structure of the second pixel electrode and the second light emitting element.

FIG. 9 is a layout diagram illustrating pixels of a display area according to one or more embodiments.

FIG. 10 is a cross-sectional view illustrating one example of a cross-section of a display panel corresponding to the line I2-I2' of FIG. 9.

FIG. 11 is a cross-sectional view illustrating in detail one example of an area B of FIG. 10.

FIG. 12 is a cross-sectional view illustrating in detail one example of the bonding structure of the first pixel electrode and the first light emitting element of FIG. 10 and the bonding structure of the second pixel electrode and the second light emitting element.

FIGS. 13 and 14 are cross-sectional views illustrating another embodiment of the first light emitting element of FIG. 12.

FIG. 15 is a cross-sectional view illustrating one example of a cross-section of a display panel corresponding to the line I2-I2' of FIG. 9 according to one or more embodiments.

FIG. 16 is a cross-sectional view illustrating one example of an area B2 of FIG. 15 in detail.

FIG. 17 is a cross-sectional view illustrating one example of the area B2 of FIG. 15 in detail according to one or more embodiments.

FIG. 18 is a cross-sectional view illustrating one example of the bonding structure of the first pixel electrode and the first light emitting element and the bonding structure of the second pixel electrode and the second light emitting element of FIG. 15 in detail.

FIG. 19 is a cross-sectional view illustrating one example of a cross-section of a display panel corresponding to the line I2-I2' of FIG. 9 according to one or more embodiments.

FIG. 20 is a flowchart illustrating a method of manufacturing a display device according to one or more embodiments.

FIGS. 21 – 27 are cross-sectional views illustrating manufacturing steps of a display device according to one or more embodiments.

FIGS. 28 and 29 are example drawings illustrating a smart watch including a display device according to one or more embodiments.

FIG. 30 is an exploded perspective view of a smart watch including a display device according to one or more embodiments.

FIGS. 31 is an example views of a virtual reality (VR) device including a display device according to one or more embodiments.

FIG. 32 is an example view of a VR device including a display device according to one or more embodiments.

FIG. 33 is an example view illustrating a vehicle instrument cluster and center fascia including display devices according to one or more embodiments.

FIG. 34 is an example view of a transparent display device including a display device according to one or more embodiments.

### DETAILED DESCRIPTION

Aspects and features of embodiments of the present disclosure and methods of accomplishing the same may be understood more readily by reference to the detailed description of embodiments and the accompanying drawings. Hereinafter, aspects of some embodiments will be described in more detail with reference to the accompanying drawings. The described embodiments, however, may be embodied in various different forms, and should not be construed as being limited to only the illustrated embodiments herein. Rather, these embodiments are provided as examples so that the present disclosure will be thorough and complete, and will fully convey the aspects and features of the present disclosure to those skilled in the art. Accordingly, processes, elements, and techniques that are not necessary to those having ordinary skill in the art for a complete understanding of the aspects and features of the present disclosure might not be described.

Unless otherwise noted, like reference numerals, characters, or combinations thereof denote like elements throughout the attached drawings and the written description, and thus, descriptions thereof will not be repeated. Further, parts not related to the description of one or more embodiments might not be shown to make the description clear.

In the drawings, the relative sizes of elements, layers, and regions may be exaggerated for clarity. Additionally, the use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified.

Various embodiments are described herein with reference to sectional illustrations that are schematic illustrations of embodiments and/or intermediate structures. As such, variations from the shapes of the illustrations as a result, for example, of manufacturing techniques and/or tolerances, are to be expected. Further, specific structural or functional descriptions disclosed herein are merely illustrative for the purpose of describing embodiments according to the present disclosure. Thus, embodiments disclosed herein should not be construed as limited to the particular illustrated shapes of regions, but are to include deviations in shapes that result from, for instance, manufacturing.

For example, an implanted region illustrated as a rectangle may have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the drawings are schematic in nature and their shapes are not intended to illustrate the actual shape of a region of a device and are not intended to be limiting. Additionally, as those skilled in the art would realize, the described embodiments may be modified in various different ways, all without departing from the spirit and/or scope of the present disclosure.

In the detailed description, for the purposes of explanation, numerous specific details are set forth to provide a thorough understanding of various embodiments. It is apparent, however, that various embodiments may be practiced without these specific details or with one or more equivalent arrangements. In other instances, well-known structures and devices are shown in block diagram form to avoid unnecessarily obscuring various embodiments.

Spatially relative terms, such as “beneath,” “below,” “lower,” “under,” “above,” “upper,” and/or the like, may be used herein for ease of explanation to describe one element or feature’s relationship to another element(s) or feature(s) as illustrated in the figures. It will be understood that the spatially relative terms are intended to encompass different orientations of the device in use or in operation, in addition to the orientation depicted in the figures. For example, if the device in the figures is turned over, elements described as “below” or “beneath” or “under” other elements or features would then be oriented “above” the other elements or features. Thus, the example terms “below” and “under” can encompass both an orientation of above and below. The device may be otherwise oriented (e.g., rotated 90 degrees or at other orientations) and the spatially relative descriptors used herein should be interpreted accordingly. Similarly, when a first part is described as being arranged “on” a second part, this indicates that the first part is arranged at an upper side or a lower side of the second part without the limitation to the upper side thereof on the basis of the gravity direction.

Further, in this specification, the phrase “on a plane,” or “in a plan view,” means viewing a target portion from the top, and the phrase “on a cross-section” means viewing a cross-section formed by vertically cutting a target portion from the side.

It will be understood that when an element, layer, region, or component is referred to as being “formed on,” “on,” “connected to,” or “coupled to” another element, layer, region, or component, it can be directly formed on, on, connected to, or coupled to the other element, layer, region, or component, or indirectly formed on, on, connected to, or coupled to the other element, layer, region, or component such that one or more intervening elements, layers, regions, or components may be present. For example, when a layer, region, or component is referred to as being "electrically connected" or "electrically coupled" to another layer, region, or component, it can be directly electrically connected or coupled to the other layer, region, and/or component or intervening layers, regions, or components may be present. However, “directly connected/directly coupled” refers to one component directly connecting or coupling another component without an intermediate component. Meanwhile, other expressions describing relationships between components such as “between,” “immediately between” or “adjacent to” and “directly adjacent to” may be construed similarly. In addition, it will also be understood that when an element or layer is referred to as being “between” two elements or layers, it can be the only element or layer between the two elements or layers, or one or more intervening elements or layers may also be present.

For the purposes of the present disclosure, expressions such as “at least one of,” “one of,” and “selected from,” when preceding a list of elements, modify the entire list of elements and do not modify the individual elements of the list. For example, “at least one of X, Y, and Z,” “at least one of X, Y, or Z,” and “at least one selected from the group consisting of X, Y, and Z” may be construed as X only, Y only, Z only, any combination of two or more of X, Y, and Z, such as, for instance, XYZ, XYY, XZ, YZ, and ZZ, or any variation thereof. Similarly, the expression such as "at least one of A and/or B" may include A, B, or A and B. As used herein, the term “and/or” includes any and all combinations of one or more of the associated listed items. For example, the expression such as "A and/or B" may include A, B, or A and B. Further, the use of “may” when describing embodiments of the present disclosure refers to “one or more embodiments of the present disclosure".

It will be understood that, although the terms “first,” “second,” “third,” etc., may be used herein to describe various elements, components, regions, layers and/or sections, these elements, components, regions, layers and/or sections should not be limited by these terms. These terms are used to distinguish one element, component, region, layer or section from another element, component, region, layer or section. Thus, a first element, component, region, layer or section described below could be termed a second element, component, region, layer or section, without departing from the spirit and scope of the present disclosure.

In the examples, the x-axis, the y-axis, and/or the z-axis are not limited to three axes of a rectangular coordinate system, and may be interpreted in a broader sense. For example, the x-axis, the y-axis, and the z-axis may be perpendicular to one another, or may represent different directions that are not perpendicular to one another. The same applies for first, second, and/or third directions.

The terminology used herein is for the purpose of describing particular embodiments only and is not intended to be limiting of the present disclosure. As used herein, the singular forms “a” and “an” are intended to include the plural forms as well, unless the context clearly indicates otherwise. It will be further understood that the terms “comprises,” “comprising,” “have,” “having,” “includes,” and “including,” when used in this specification, specify the presence of the stated features, integers, steps, operations, elements, and/or components, but do not preclude the presence or addition of one or more other features, integers, steps, operations, elements, components, and/or groups thereof.

As used herein, the term “substantially,” “about,” “approximately,” and similar terms are used as terms of approximation and not as terms of degree, and are intended to account for the inherent deviations in measured or calculated values that would be recognized by those of ordinary skill in the art. “About” or “approximately,” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ± 30%, 20%, 10%, 5% of the stated value. Further, the use of “may” when describing embodiments of the present disclosure refers to “one or more embodiments of the present disclosure.”

When one or more embodiments may be implemented differently, a specific process order may be performed differently from the described order. For example, two consecutively described processes may be performed substantially at the same time or performed in an order opposite to the described order.

Also, any numerical range disclosed and/or recited herein is intended to include all sub-ranges of the same numerical precision subsumed within the recited range. For example, a range of “1.0 to 10.0” is intended to include all subranges between (and including) the recited minimum value of 1.0 and the recited maximum value of 10.0, for example, having a minimum value equal to or greater than 1.0 and a maximum value equal to or less than 10.0, such as, for example, 2.4 to 7.6. Any maximum numerical limitation recited herein is intended to include all lower numerical limitations subsumed therein, and any minimum numerical limitation recited in this specification is intended to include all higher numerical limitations subsumed therein. Accordingly, Applicant reserves the right to amend this specification, including the claims, to expressly recite any sub-range subsumed within the ranges expressly recited herein. All such ranges are intended to be inherently described in this specification such that amending to expressly recite any such subranges would comply with the requirements of 35 U.S.C. § 112(a) and 35 U.S.C. § 132(a).

The electronic or electric devices and/or any other relevant devices or components according to one or more embodiments of the present disclosure described herein may be implemented utilizing any suitable hardware, firmware (e.g., an application-specific integrated circuit), software, or a combination of software, firmware, and hardware. For example, the various components of these devices may be formed on one integrated circuit (IC) chip or on separate IC chips. Further, the various components of these devices may be implemented on a flexible printed circuit film, a tape carrier package (TCP), a printed circuit board (PCB), or formed on one substrate.

Further, the various components of these devices may be a process or thread, running on one or more processors, in one or more computing devices, executing computer program instructions and interacting with other system components for performing the various functionalities described herein. The computer program instructions are stored in a memory which may be implemented in a computing device using a standard memory device, such as, for example, a random access memory (RAM). The computer program instructions may also be stored in other non-transitory computer readable media such as, for example, a CD-ROM, flash drive, and/or the like. Also, a person of skill in the art should recognize that the functionality of various computing devices may be combined or integrated into a single computing device, or the functionality of a particular computing device may be distributed across one or more other computing devices without departing from the spirit and scope of the present disclosure.

Unless otherwise defined, all terms (including technical and scientific terms) used herein have the same meaning as commonly understood by one of ordinary skill in the art to which the present disclosure belongs. It will be further understood that terms, such as those defined in commonly used dictionaries, should be interpreted as having a meaning for example consistent with their meaning in the context of the relevant art and/or the present specification, and should not be interpreted in an idealized or overly formal sense, unless expressly so defined herein.

A person of ordinary skill in the art would appreciate, in view of the present disclosure in its entirety, that each suitable feature of the various embodiments of the present disclosure may be combined or combined with each other, partially or entirely, and may be technically interlocked and operated in various suitable ways, and each embodiment may be implemented independently of each other or in conjunction with each other in any suitable manner unless otherwise stated or implied.

Hereinafter, embodiments of the present disclosure are described with reference to the drawings.

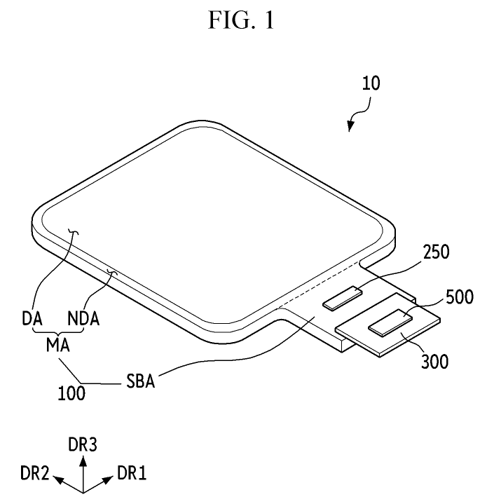

FIG. 1 is a perspective view illustrating a display device according to one or more embodiments.

Referring to FIG. 1, the display device 10 is a device for displaying video and/or still images, and may be a mobile phone, a smart phone, a tablet personal computer, and a portable electronic device such as a smart watch, a watch phone, a mobile communication terminal, an electronic notebook, an e-book, portable electronic devices such as portable multimedia players (PMP), navigation systems, ultra mobile PC (UMPC), and/or the like, as well as a variety of electronic devices such as televisions, laptops, monitors, billboards, internet of things (IOT) devices, and/or the like, which may be included and used as display screens. Also, the display device 10 may be included in other electronic devices such as a virtual reality (VR) device or an augmented reality (AR) device and used to display an image in the electronic devices. In one or more embodiments, an electronic device including the display device 10 may further include a display device storage portion in which the display device 10 is stored, and/or a case or a cover for protecting the display device 10.

In one or more embodiments, the display device 10 may be a light emitting display device, such as an organic light-emitting display device utilizing an organic light-emitting diode (OLED), a quantum dot light-emitting display device including a quantum dot light-emitting layer, an inorganic light-emitting display device including an inorganic semiconductor, and a miniaturized light-emitting display device utilizing a micro or nano light emitting diode (micro LED or nano LED). Hereinafter, the description focuses on the fact that the display device 10 is a micro-light emitting display device, but the present disclosure is not limited thereto. On the other hand, hereinafter, an ultra-small light emitting diode is described as a light emitting element for convenience of explanation.

The display device 10 includes a display panel 100, a display driving circuit 250, a circuit substrate 300, and a power supply circuit 500.

The display panel 100 may be formed as a rectangular shaped plane having a short side in the first direction DR1 and a long side in the second direction DR2 that intersects the first direction DR1. A corner where the short side in the first direction DR1 and the long side in the second direction DR2 meet may be rounded to have a suitable curvature (e.g., a predetermined curvature) or may be formed at a right angle. The planar shape of the display panel 100 is not limited to a rectangle, but may be formed in other polygonal, circular, or oval shapes. The display panel 100 may be formed flat but is not limited thereto. In one example, the display panel 100 may be formed at the left and right ends and may include curved portions with a constant curvature or a changing curvature. In addition, the display panel 100 may be flexibly formed to be bent, curved, bent, folded, and/or rolled.

The display panel 100 may include the main area MA and the sub-area SBA.

The main area MA may include a display area DA that displays an image and a non-display area NDA that is a surrounding area of the display area DA. The display area DA may include a plurality of pixels that display an image. Each pixel may include a plurality of sub-pixels. For example, each of the pixels may include a first sub-pixel that emits light of a first color (or first light), a second sub-pixel that emits light of a second color (or second light), and a third sub-pixel that emits light of a third color (or third light), but the present disclosure is not limited thereto.

The sub-area SBA may protrude from one side of the main area MA in a second direction DR2 (e.g., in the longitudinal direction of the display panel 100). In FIG. 1, the sub-area SBA is illustrated as being unfolded, but the sub-area SBA may be bent, in which case it may be arranged on the bottom surface of the display panel 100. When the sub-area SBA is bent, it may overlap the main area MA in a third direction DR3, which is the thickness direction of the display panel 100. A display driving circuit 250 may be arranged in the sub-area SBA.

The display driving circuit 250 may generate signals and voltages for driving the display panel 100. The display driving circuit 250 may be formed as an integrated circuit (IC) and attached to the indication panel 100 using a chip on glass (COG) method, a chip on plastic (COP) method, or an ultrasonic bonding method but is not limited thereto. In one or more embodiments, the display driving circuit 250 may be attached to the circuit substrate 300 using a chip on film (COF) method.

The circuit substrate 300 may be attached to one end of the sub-area SBA of the display panel 100. As such, the circuit substrate 300 may be electrically connected to the display panel 100 and the display driving circuit 250. The display panel 100 and the display driving circuit 250 may receive digital video data, timing signals, and driving voltages through the circuit substrate 300. The circuit substrate 300 may be a flexible film, such as a flexible printed circuit substrate, a printed circuit substrate, or a chip on film.

The power supply circuit 500 may generate a plurality of panel driving voltages according to an external power supply voltage. The power supply circuit 500 may be formed as an integrated circuit (IC) and attached to the circuit substrate 300 using a COF method.

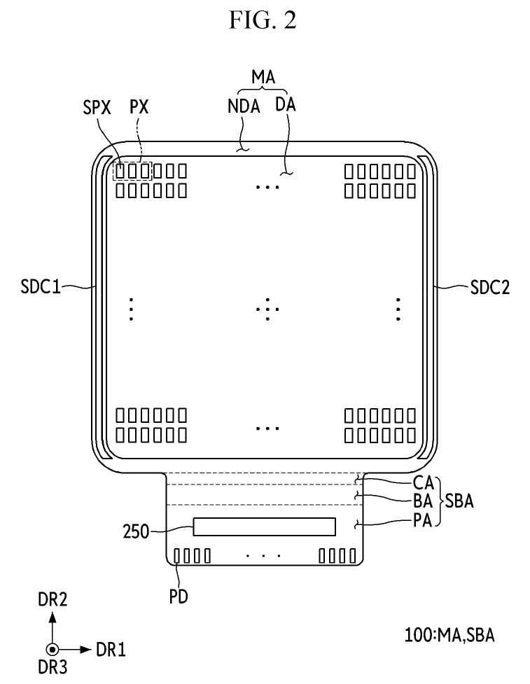

FIG. 2 is a layout diagram (e.g., a plan view drawing) illustrating a display panel according to one or more embodiments. FIG. 2 illustrates that the sub-area SBA is unfolded without being bent.

Referring to FIGS. 1 and 2, the display panel 100 may include the main area MA and the sub-area SBA.

The main area MA may include the display area DA that displays an image and the non-display area NDA that is a peripheral area of the display area DA. The display area DA may occupy most of the main area MA. The display area DA may be placed in the center of the main area MA.

The display area DA includes pixels PX for displaying an image, and each pixel PX may include a plurality of sub-pixels SPX. A pixel PX may be defined as a sub-pixel group that is the smallest unit capable of expressing white gradation (e.g., a white gray level).

The non-display area NDA may be arranged adjacent to the display area DA. The non-display area NDA may be an area outside the display area DA. The non-display area NDA may be arranged to be around (e.g., to surround) the display area DA. The non-display area NDA may be an edge area of the display panel 100.

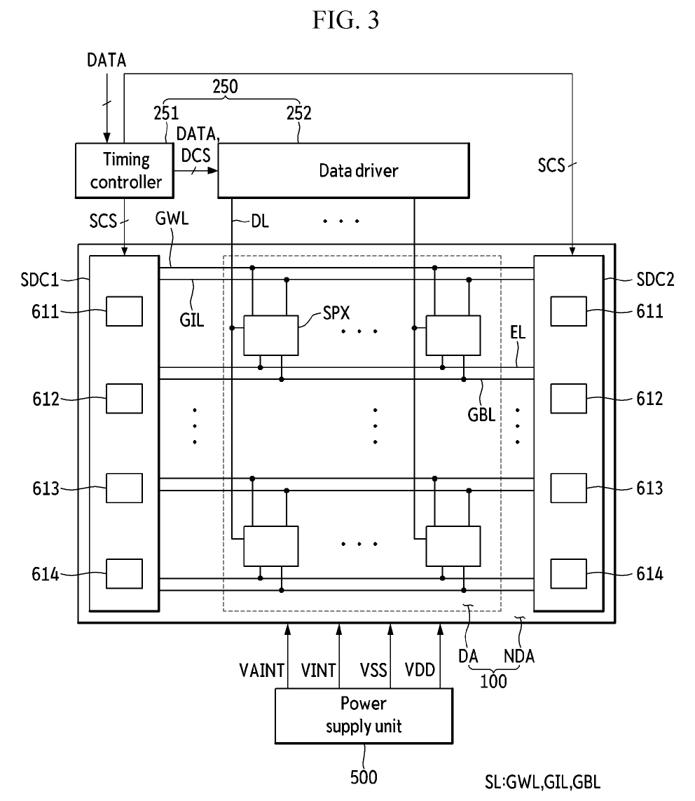

A first scan driving portion SDC1 and a second scan driving portion SDC2 may be arranged in a non-display area NDA. The first scan driving portion SDC1may be arranged on one side (e.g., the left side) of the display panel 100, and second scan driving portion SDC2 may be arranged on the other side (e.g., the right side) of the display panel, but is not limited thereto. Each of the first scan driving portion SDC1 and the second scan driving portion SDC2 may be electrically connected to a display driving circuit 250 through scan fan out lines. Each of the first scan driving portion SDC1 and the second scan driving portion SDC2 may receive a scan control signal from the display driving circuit 250, generate scan signals according to the scan control signal, and output them to scan lines. The configuration and operation of the first scan driving portion SDC1 and the second scan driving portion SDC2 will be described in detail with reference to FIGS. 3 – 7.

The sub-area SBA may protrude from one side of the main area MA in the second direction DR2. The length of the sub-area SBA in the second direction DR2 may be smaller than the length of the main area MA in the second direction DR2. The length in the first direction DR1 of the sub area SBA may be less than the length in the first direction DR1 of the main area MA or may be substantially equal to the length in the first direction DR1 of the main area MA. The sub-area SBA may be curved and arranged below the main area MA. In this case, the sub-area SBA may overlap the main area MA in the third direction DR3.

The sub-area SBA may include a connection area CA, a pad area PA, and a bending area BA.

The connection area CA is an area protruding from one side of the main area MA in the second direction DR2. One side of the connection area CA may be in contact with the non-display area NDA of the main area MA, and the other side of the connection area CA may be in contact with the bending area BA.

The pad area PA is an area where the pads PD and the display driving circuit 250 are arranged. The display driving circuit 250 may be attached to the driving pads of the pad area PA using a conductive adhesive member such as an anisotropic conductive film. The circuit substrate 300 may be attached to the pads PD of the pad area PA using a conductive adhesive member such as an anisotropic conductive film. One side of the pad area PA may be in contact with the bending area BA.

The bending area BA is a bent area. When the bending area BA is bent, the pad area PA may be arranged below the connection area CA and below the main area MA. The bending area BA may be arranged between the connection area CA and the pad area PA. One side of the bending area BA may be in contact with the connection area CA, and the other side of the bending area BA may be in contact with the pad area PA.

FIG. 3 is a block drawing illustrating a display device according to one or more embodiments.

The pixels PX may be arranged along the first direction DR1 and the second direction DR2. For example, the pixels PX may be arranged in a matrix form along the first direction DR1 and the second direction DR2. For example, the plurality of pixels PX may be arranged along rows and columns of a matrix along the first direction DR1 and the second direction DR2. The scan lines SL and the light emitting control lines EL may extend in the first direction DR1 and be arranged or placed along the second direction DR2. The data lines DL may extend in the second direction DR2 and may be arranged or placed along the first direction DR1. The scan lines SL may include write scan lines GWL, initialization scan lines GIL, and bias scan lines GBL. The configuration or number of the scan lines SL may vary depending on the structure or driving method of the pixels PX. In one or more embodiments, the scan lines SL may also include a plurality of control scan lines GCL.

Each of the pixels PX may include a plurality of sub-pixels SPX. For example, each of the pixels PX may include a first sub-pixel SPX1, a second sub-pixel SPX2, and a third sub-pixel SPX3. The first sub-pixel SPX1, the second sub-pixel SPX2, and the third sub-pixel SPX3 may emit light of a first color, light of a second color, and light of a third color, respectively. The light of the first color, light of the second color, and light of the third color may be, but are not limited to, red light (e.g., light in a red wavelength band having a main peak wavelength of about 600 nm to 750 nm), green light (e.g., light in a green wavelength band having a main peak wavelength of about 480 nm to 560 nm), and blue light (e.g., light in a blue wavelength band having a main peak wavelength of about 370 nm to 460 nm), respectively. In one or more embodiments, the first sub-pixel SPX1, the second sub-pixel SPX2, and the third sub-pixel SPX3 of each of the pixels PX may be arranged in the first direction DR1. The number, type, arrangement structure, and/or light emitting wavelength of the sub-pixels SPX included in each of the pixels PX may be variously changed according to embodiments.

Each of the plurality of sub-pixels SPX may be connected to one of the write scan lines GWL, one of the initialization scan lines GIL, one of the bias scan lines GBL, one of the light emitting control lines EL, and one of the data lines DL. In one or more embodiments, each of the plurality of sub-pixels SPX may also be connected to a control scan line GCL from among the plurality of control scan lines GCL. In describing the embodiments, the term “connection” may include the meaning of “physical connection” and/or “electrical connection.”

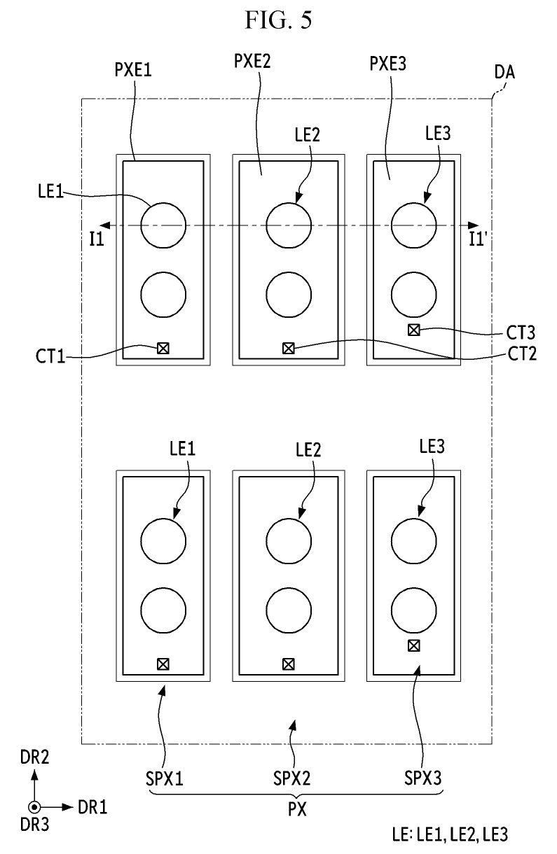

Each of the plurality of sub-pixels SPX may be supplied with a data voltage of a data line DL according to a write scan signal of a write scan line GWL and may emit light from a light emitting element according to the data voltage. The plurality of sub-pixels SPX included in each pixel PX may be connected to different data lines DL. For example, the first sub-pixel SPX1, the second sub-pixel SPX2, and the third sub-pixel SPX3 (e.g., see FIG. 5) may be connected to a first data line DLr, a second data line DLg, and a third data line DLb, respectively, of the data lines DL. Accordingly, the light-emitting luminance of each of the first sub-pixel SPX1, the second sub-pixel SPX2, and the third sub-pixel SPX3 may be individually controlled.

In one or more embodiments, each of the pixels PX is connected to two or more light emitting control lines EL, and the light emitting periods (or on-duty ratios) of at least two sub-pixels SPX among the plurality of sub-pixels SPX included in each pixel PX may be independently and/or individually controlled by different light emitting control signals supplied to the different light emitting control lines EL. For example, in one or more embodiments, the light emitting control lines EL may include a first light emitting control line EL1 and a second light emitting control line EL2, and in each horizontal line (e.g., each pixel row) of the display area DA, a first light emitting control line EL1 and a second light emitting control line EL2 may be arranged, which are connected to different sub-pixels SPX among the sub-pixels SPX included in the pixels PX arranged in the corresponding horizontal line. For example, in one or more embodiments, the first light emitting control line EL1 may be connected to the first sub-pixels SPX1 of the pixels PX arranged in the corresponding horizontal line, and the second light emitting control line EL2 may be connected to the second sub-pixels SPX2 and the third sub-pixels SPX3 included in the pixels PX of the corresponding horizontal line.

The first scan driving portion SDC1, the second scan driving portion SDC2, and a display driving circuit 250 may be arranged in the non-display area NDA.

Each of the first scan driving portion SDC1 and the second scan driving portion SDC2 may include a write scan signal output portion 611, an initialization scan signal output portion 612, a bias scan signal output portion 613, and an emission control signal output portion 614.

In one or more embodiments, the emission control signal output portion 614 may include a first light emitting driver and a second light emitting driver.

In one or more embodiments, the first light emitting driver may be connected to the first light emitting control line EL1. In one or more embodiments, the second light emitting driver may be connected to the second light emitting control line EL2.

In one or more embodiments, the first sub-pixel SPX1 may emit light during a first light emitting period in response to a first light emitting control signal supplied through the first light emitting control line EL1. The first light emitting period may be a period during which a driving current may flow to the first sub-pixel SPX1 by the first light emitting control signal. The second sub-pixel SPX2 and the third sub-pixel SPX3 may emit light during a second light emitting period in response to a second light emitting control signal supplied through the second light emitting control line EL2. The second light emitting period may be a period during which a driving current may flow to the second sub-pixel SPX2 and the third sub-pixel SPX3 by the second light emitting control signal. The first light emitting period and the second light emitting period may be controlled independently or separately from each other and may or may not temporally overlap each other.

In one or more embodiments, the duration of the first light emitting period and the duration of the second light emitting period may be different. For example, the duration of the first light emitting period may correspond to an on-duty ratio adjusted so that the first sub-pixel SPX1 emits light with a target luminance according to a driving current optimized for the light emitting efficiency of the first sub-pixel SPX1 (e.g., a driving current within a range in which the light emitting element of the first sub-pixel SPX1 exhibits optimal consumption efficiency).

The duration of the second light emitting period may correspond to an on-duty ratio adjusted so that the second sub-pixel SPX2 and the third sub-pixel SPX3 emit light with a target luminance at a driving current optimized for the light emitting efficiency of the second sub-pixel SPX2 and the third sub-pixel SPX3 (e.g., a driving current within a range where the light emitting elements of the second sub-pixel SPX2 and the third sub-pixel SPX3 exhibit optimal consumption efficiency).

Each of the first scan driving portion SDC1 and the second scan driving portion SDC2 may be electrically connected to the pixels PX through scan lines SL. For example, each of the first scan driving portion SDC1 and the second scan driving portion SDC2 may be electrically connected to pixel circuits of the sub-pixels SPX included in each pixel PX through write scan lines GWL, initialization scan lines GIL, and bias scan lines GBL.

Each of the first scan driving portion SDC1 and the second scan driving portion SDC2 may include a write scan signal output portion 611, an initialization scan signal output portion 612, a bias scan signal output portion 613, and an emission control signal output portion 614. Each of the write scan signal output portion 611, the initialization scan signal output portion 612, the bias scan signal output portion 613, and the emission control signal output portion 614 may receive a scan timing control signal SCS from a timing control circuit (e.g., a timing controller) 251. .

The write scan signal output portion 611 may generate write scan signals according to the scan timing control signal SCS of the timing control circuit 251 and sequentially output them to the write scan lines GWL..

The initialization scan signal output portion 612 may generate initialization scan signals according to the scan timing control signal SCS and sequentially output them to the initialization scan lines GIL. The bias scan signal output portion 613 may generate bias scan signals according to the scan timing control signal SCS and sequentially output them to the bias scan lines GBL.

The emission control signal output portion 614 may generate emission control signals according to the scan timing control signal SCS and sequentially output them to the emission control lines EL. When the sub-pixels SPX of each horizontal line are divided and connected to a plurality of light emitting control lines EL (e.g., the first light emitting control line EL1 and the second light emitting control line EL2 of each horizontal line), the emission control signal output portion 614 may output each light emitting control signal to the plurality of light emitting control lines EL for each horizontal period.

The display driving circuit 250 may include a timing control circuit (e.g., a timing controller) 251 and a data driving circuit (e.g., a data driver) 252.

The data driving circuit 252 may be electrically connected to the pixels PX through the data lines DL. For example, the data driving circuit 252 may be electrically connected to the pixel circuits of the sub-pixels SPX included in each pixel PX through the first data line DLr, the second data line DLg, and the third data line DLb.

The data driving circuit 252 may receive digital video data DATA and a data timing control signal DCS from the timing control circuit 251. The data driving circuit 252 converts the digital video data DATA into analog data voltages according to the data timing control signal DCS and outputs the converted data to the data lines DL. In this case, the sub-pixels SPX are selected by the write scan signal of the first scan driving unit SDC1 and the second scan driving unit SDC2, and the selected sub-pixels.

The timing control circuit 251 may receive digital video data DATA and timing signals from the outside. The timing control circuit 251 may generate a scan timing control signal SCS and a data timing control signal DCS for controlling the display panel 100 according to the timing signals. The timing control circuit 251 may output the scan timing control signal SCS to the first scan driving unit SDC1 and the second scan driving unit SDC2. The timing control circuit 251 may output digital video data DATA and a data timing control signal DCS to the data driving circuit 252.

The power supply circuit (e.g., the power supply unit) 500 may generate panel driving voltages according to a power voltage supplied from the outside. For example, the power supply circuit 500 may generate a first driving voltage VDD, a second driving voltage VSS, a third driving voltage VINT, and a fourth driving voltage VAINT, and supply them to the display panel 100. In one or more embodiments, the power supply circuit 500 may also generate a fifth driving voltage VOBS. The first driving voltage VDD, the second driving voltage VSS, the third driving voltage VINT, and the fourth driving voltage VAINT are supplied to the sub-pixels SPX through respective power supply lines connected between the power supply circuit 500 and the sub-pixels SPX and may be used to drive the sub-pixels SPX. Depending on the structure or operation method of the sub-pixels SPX, the number and/or types of panel driving voltages output from the power supply circuit 500 may change.

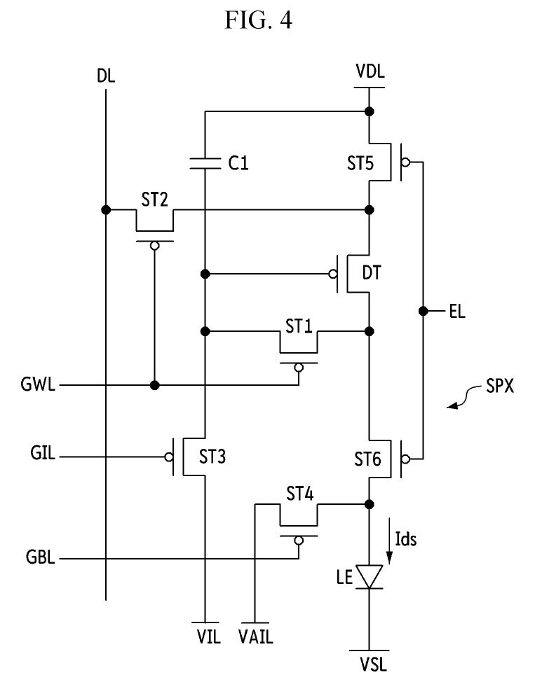

FIG. 4 is an equivalent circuit diagram illustrating a sub-pixel according to one or more embodiments.

Referring to FIG. 4, a sub-pixel SPX according to one or more embodiments may be connected to scan lines GWL, GIL, and GBL, an emission control line EL, and a data line DL. For example, the sub-pixel SPX may be connected to a write scan line GWL, an initialization scan line GIL, a bias scan line GBL, an emission control line EL, and a data line DL.

The sub-pixel SPX according to one or more embodiments includes a driving transistor DT, switching elements, a capacitor C1, and a lighting element LE. The switching elements include first to sixth transistors ST1, ST2, ST3, ST4, ST5, and ST6.

The driving transistor DT includes a gate electrode, a first electrode, and a second electrode. The driving transistor DT controls a drain-source current (Ids, hereinafter referred to as "driving current") flowing between the first electrode and the second electrode according to a data voltage applied to a gate electrode of the driving transistor DT.

The light emitting element LE may be a micro light emitting diode.

The light emitting element LE emits light according to the driving current Ids. The amount of light emitted from the light emitting element LE may be proportional to the driving current Ids. The anode electrode of the light emitting element LE is connected to the first electrode of the fourth transistor ST4 and the second electrode of the sixth transistor ST6, and the cathode electrode may be connected to a second power supply line VSL to which a second power supply voltage is applied.

A capacitor C1 is formed between the gate electrode of a driving transistor DT and a first power supply line VDL to which a first power supply voltage is applied. The first power supply voltage may be a voltage of a higher level than the second power supply voltage. One electrode of the capacitor C1 may be connected to the gate electrode of the driving transistor DT, and the other electrode may be connected to the first power supply line VDL.

As shown in FIG. 4, the first to sixth transistors ST1, ST2, ST3, ST4, ST5, and ST6 and the driving transistor DT may all be formed as p-type MOSFET. In this case, the active layer of each of the first to sixth transistors ST1, ST2, ST3, ST4, ST5, and ST6 and the driving transistor DT may be formed of polysilicon.

The gate electrode of the first transistor ST1 and the gate electrode of the second transistor ST2 may be connected to the write scan line GWL, the gate electrode of the third transistor ST3 may be connected to the initialization scan line GIL, and the gate electrode of the fourth transistor ST4 may be connected to the bias scan line GBL. Because the first to sixth transistors ST1, ST2, ST3, ST4, ST5, and ST6 are formed as p-type MOSFET, they may be turned on when a scan signal of a gate low voltage and an emission control signal of a gate low voltage are applied to the initialization scan line GIL, the write scan line GWL, the bias scan line GBL, and the emission line EL, respectively. One electrode of the third transistor ST3 may be connected to the first initialization voltage line VIL to which the third power supply voltage (e.g., the third driving voltage VINT of FIG. 3) is applied, and one electrode of the fourth transistor ST4 may be connected to the second initialization voltage line VAIL to which the fourth power supply voltage (e.g., the fourth driving voltage VAINT of FIG. 3) is applied. The third power supply voltage (VINT of FIG. 3) and the fourth power supply voltage (VAINT of FIG. 3) may be different voltages. Further, the third power supply voltage (VINT in FIG. 3) and the fourth power supply voltage (VAINT in FIG. 3) may be voltages at a lower level than the first power supply voltage (e.g., the first driving voltage VDD) and at a higher level than the second power supply voltage (e.g., the second driving voltage VSS).

Alternatively, the driving transistor DT, the second transistor ST2, the fourth transistor ST4, the fifth transistor ST5, and the sixth transistor ST6 may be formed of a p-type MOSFET, and the first transistor ST1 and the third transistor ST3 may be formed of an n-type MOSFET. In this case, the active layers of each of the driving transistor DT, the second transistor ST2, the fourth transistor ST4, the fifth transistor ST5, and the sixth transistor ST6 formed of p-type MOSFETs are formed of polysilicon, the active layers of each of the first transistor ST1 and the third transistor ST3 formed of an n-type MOSFET may be formed of an oxide semiconductor. Furthermore, because the first transistor ST1 and the third transistor ST3 are formed as n-type MOSFET, the first transistor ST1 may be turned on when a write scan signal of the gate high voltage is applied, and the third transistor ST3 may be turned on when an initialization scan signal of the gate high voltage is applied. In contrast, the second transistor ST2, the fourth transistor ST4, the fifth transistor ST5, and the sixth transistor ST6 are formed as p-type MOSFET, so they may be turned on when a scan signal of the gate low voltage and a light emission control signal of a gate low voltage are applied.

Alternatively, the fourth transistor ST4 may be formed as an n-type MOSFET, and the remaining transistors DT, ST1, ST2, ST3, ST5, and ST6 may be formed as p-type MOSFET, in which case the active layer of the fourth transistor ST4 may be formed as an oxide semiconductor, and the active layers of each of the remaining transistors DT, ST1, ST2, ST3, ST5, and ST6 may be formed as polysilicon. Further, the fourth transistor ST4 may be turned on when a scan signal of a gate high voltage is applied, whereas the remaining transistors DT, ST1, ST2, ST3, ST5, and ST6 may be turned on when a scan signal of a gate low voltage and a light emission control signal of a gate low voltage are applied.

Alternatively, the first to sixth transistors ST1, ST2, ST3, ST4, ST5, and ST6 and the driving transistor DT may all be formed as n-type MOSFET. In this case, the active layer of each of the first to sixth transistors ST1, ST2, ST3, ST4, ST5, and ST6 and the driving transistor DT is formed of an oxide semiconductor and may be turned on when a scan signal of a gate high voltage and a light emission control signal are applied.

In general, semiconductor light emitting elements (hereinafter, micro LED) with a diameter or major axis length of several to several hundred micrometers tend to have lower external quantum efficiency EQE than light emitting elements of relatively large sizes. The external quantum efficiency may generally mean the number of photons generated relative to the injected carriers. In particular, the carrier leakage may be severe at low currents in the early stages of operation, which may result in a decrease in the luminance of the element.

In one or more embodiments, the external quantum efficiency of the red-light emitting element R is significantly lower than that of the blue-light emitting element B or the green-light emitting element G. Also, even in the optimal current density range that produces the optimal external quantum efficiency, the red-light emitting element R is significantly lower than that of the blue-light emitting element B or the green-light emitting element G.

The on-duty ratio of a light emitting element that generally emits a red wavelength is low, whereas the on-duty ratio of a light emitting element that emits a blue wavelength or a green wavelength may be relatively high. Nevertheless, when the on-duty ratios of the light emitting element that emits a red wavelength and the light emitting element that emits a blue wavelength or a green wavelength are identically reflected, the light emitting element that emits a red wavelength uses a low current density section, which increases power consumption. Therefore, in one or more embodiments, the light emitting control signals that control the light emitting element that emits a red wavelength and the light emitting control signals that control the light emitting element that emits a blue wavelength or a green wavelength are separately operated by applying a first light emitting driver and a second light emitting driver of the emission control signal output portion 614, thereby reducing power consumption.

FIG. 5 is a layout diagram illustrating pixels of a display area according to one or more embodiments.

Referring to FIG. 5, each of the plurality of pixels PX of the display area DA may include three sub-pixels SPX1, SPX2, and SPX3, but the present disclosure is not limited thereto and may include four sub-pixels. When each of the plurality of pixels PX includes three sub-pixels, the three sub-pixels may be the first sub-pixel SPX1, the second sub-pixel SPX2, and the third sub-pixel SPX3 may include.

The plurality of pixels PX may be arranged in a matrix form. In each of the plurality of pixels PX, the first sub-pixel SPX1, the second sub-pixel SPX2, and the third sub-pixel SPX3 may be arranged along the first direction DR1.

When each of the plurality of pixels PX includes three sub-pixels SPX1, SPX2, and SPX3, the first sub-pixel SPX1 may emit light of a first color, the second sub-pixel SPX2 may emit light of a second color, and the third sub-pixel SPX3 may emit light of a third color. Here, the light of the first color may be light in a red wavelength band, the light of the second color may be light in a green wavelength band, and the light of the third color may be light in a blue wavelength band. For example, a third wavelength band of blue may indicate that the main peak wavelength of light is contained in a wavelength band of about 370 nm to 460 nm, a second wavelength band of green may indicate that the main peak wavelength of light is contained in a wavelength band of about 480 nm to 560 nm, and a first wavelength band of red may indicate that the main peak wavelength of light is contained in a wavelength band of about 600 nm to 750 nm.

Alternatively, when each of the plurality of pixels PX includes four sub-pixels, the first sub-pixel may emit light of a first color, the second and fourth sub-pixels may emit light of a second color, and the third sub-pixel may emit light of a third color. Alternatively, the first sub-pixel may emit light of a first color, the second sub-pixel may emit light of a second color, the third sub-pixel may emit light of a third color, and the fourth sub-pixel may emit light of a fourth color. In this case, the fourth color light may be white light.

The first sub-pixel SPX1 includes a first pixel electrode PXE1 and a plurality of first light emitting elements LE1. The second sub-pixel SPX2 includes a second pixel electrode PXE2 and a plurality of second light emitting elements LE2. The third sub-pixel SPX3 includes a third pixel electrode PXE3 and a plurality of third light emitting elements LE3.

The first light emitting element LE1 may emit light of a first color, the second light emitting element LE2 may emit light of a second color, and the third light emitting element LE3 may emit light of a third color.

Each of the first pixel electrode PXE1, the second pixel electrode PXE2, and the third pixel electrode PXE3 may have a rectangular planar shape having a short side in a first direction DR1 and a long side in a second direction DR2. The area of the first sub-pixel SPX1, the area of the second sub-pixel SPX2, and the area of the third sub- pixel SPX3 may be set according to the light-emitting efficiency of the light emitting element LE included in each sub-pixel SPX. In one example, the area of the sub-pixel may be larger as the light conversion efficiency is lower.

For example, as shown in FIG. 5, when the light-emitting efficiency of the second light emitting element LE2 of the second sub-pixel SPX2 is lower than the light-emitting efficiency of the first light emitting element LE1 of the first sub-pixel SPX1 and the third light emitting element LE3 of the third sub-pixel SPX3, the area of the second pixel electrode PXE2 may be larger than the area of the first pixel electrode PXE1 and may be larger than the area of the third pixel electrode PXE3.

Each of the pixel electrodes PXE1, PXE2, and PXE3 may be electrically connected to at least one transistor through the pixel connection hole CT1, CT2, and CT3. For example, each of the pixel electrodes PXE1, PXE2, and PXE3 may be electrically connected to the first electrode of the fourth transistor (ST4 in FIG. 4) and the second electrode of the sixth transistor (ST6 in FIG. 4) of the corresponding sub-pixel.

The plurality of light emitting elements LE may be arranged on each of the pixel electrodes PXE1, PXE2, and PXE3. The same number of light emitting elements LE may be arranged on each of the pixel electrodes PXE1, PXE2, and PXE3. For example, two light emitting elements LE may be arranged on each of the pixel electrodes PXE1, PXE2, and PXE3.

Each of the plurality of light emitting elements LE may have a circular planar shape, but the present disclosure is not limited thereto. For example, each of the plurality of light emitting elements LE may have a rectangular planar shape.

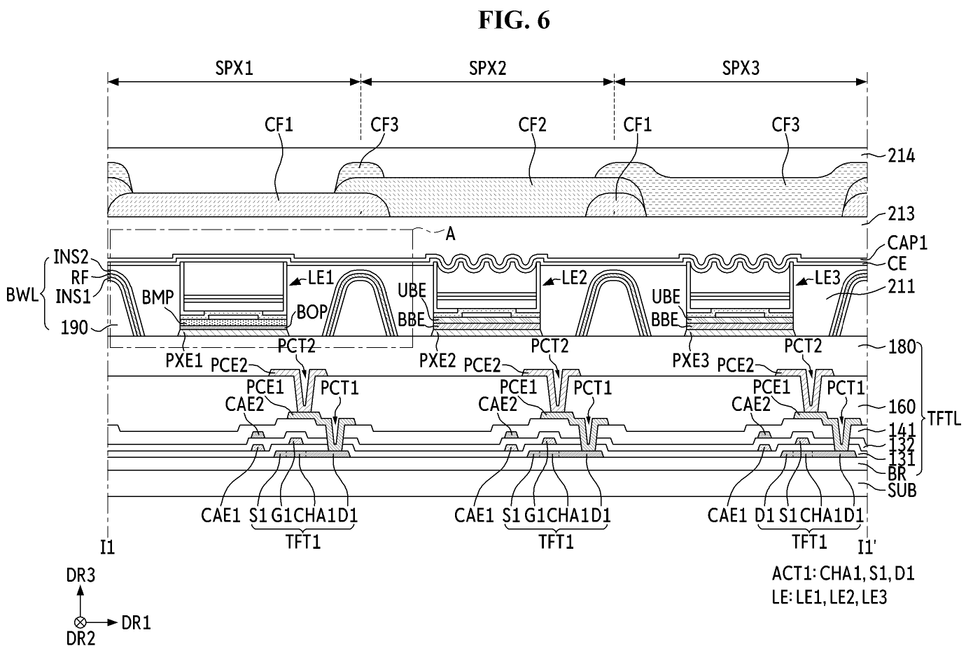

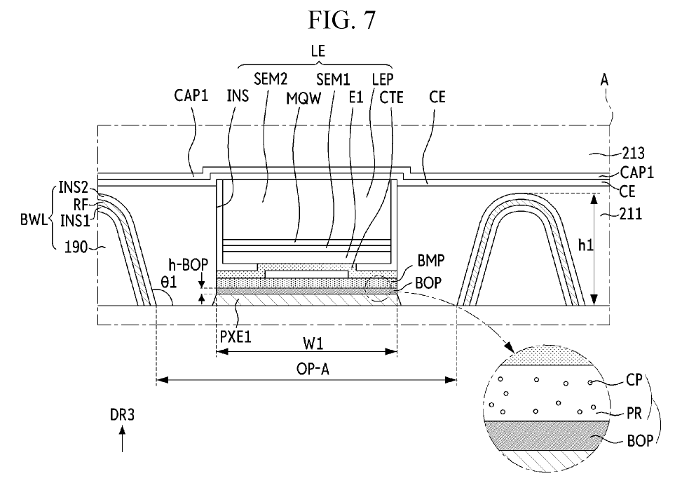

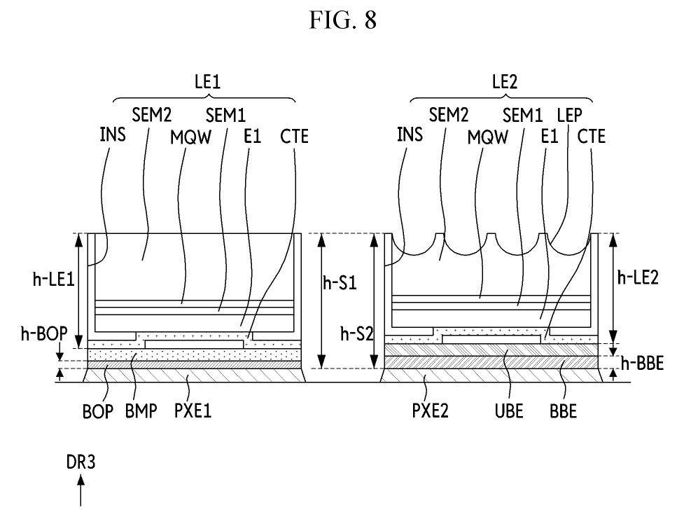

FIG. 6 is a cross-sectional view illustrating an example cross-section of one display panel corresponding to the lines I1-I1' in FIG. 5. FIG. 7 is a cross-sectional view illustrating an example of an area A in FIG. 6 in detail. FIG. 8 is a cross-sectional view illustrating in detail one example of the bonding structure of the first pixel electrode and the first light emitting element of FIG. 6 and the bonding structure of the second pixel electrode and the second light emitting element of FIG. 6.

Referring to FIGS. 6 – 8, a substrate SUB may be made of an insulating material such as glass, polymer resin, and/or the like. If the substrate SUB is made of polymer resin, it may be a flexible substrate that may be stretched. The polymer resin may be acrylic resin, epoxy resin, phenolic resin, polyamide resin, polyimide resin, and/or the like.

A barrier film BR may be arranged on the substrate SUB. The barrier film BR is a film for protecting the thin-film transistor layer TFTL from moisture penetrating through the substrate SUB which is vulnerable to moisture permeation. The barrier film BR may be formed of a plurality of inorganic films that are alternately stacked.

A thin-film transistor TFT1 may be arranged on the barrier film BR. The thin-film transistor TFT1 may be either the fourth transistor ST4 or the sixth transistor ST6 shown in FIG. 4. The thin-film transistor TFT1 may include a first active layer ACT1 and a first gate electrode G1.

The first active layer ACT1 of the thin-film transistor TFT1 may be arranged on the barrier film BR. The first active layer ACT1 of the thin-film transistor TFT1 may include polycrystalline silicon, monocrystalline silicon, low-temperature polycrystalline silicon, and/or amorphous silicon. Alternatively, the first active layer ACT1 of the thin-film transistor TFT1 may include an oxide semiconductor including IGZO (indium (In), gallium (Ga), zinc (Zn), and oxygen (O)), IGZTO (indium (In), gallium (Ga), zinc (Zn), tin (Sn), and oxygen (O)), or IGTO (indium (In), gallium (Ga), tin (Sn), and oxygen (O)).

The first active layer ACT1 may include a first channel area CHA1, a first source area S1, and a first drain area D1. The first channel area CHA1 may be an area overlapping the first gate electrode G1 in the third direction DR3, which is the thickness direction of the substrate SUB. The first source area S1 may be arranged on one side of the first channel area CHA1, and the first drain area D1 may be arranged on the other side of the first channel area CHA1. The first source area S1 and the first drain area D1 may be areas that do not overlap with the first gate electrode G1 in the third direction DR3. The first source area S1 and the first drain area D1 may be conductive areas in which semiconductor materials are doped with ions.

A first gate insulating film 131 may be arranged on the first channel area CHA1, the first source area S1, and the first drain area D1 of the thin-film transistor TFT1 and on the barrier film BR.

A first gate metal layer may be arranged on the first gate insulating film 131. The first gate metal layer may include a first gate electrode G1 of a thin-film transistor TFT1 and a first capacitor electrode CAE1. The first gate electrode G1 may overlap the first active layer ACT1 in the third direction DR3. Although the first gate electrode G1 and the first capacitor electrode CAE1 are illustrated as being arranged spaced from (e.g., spaced apart from) each other in FIG. 6, the first gate electrode G1 and the first capacitor electrode CAE1 may be connected to each other.

A second gate insulating film 132 may be arranged on the first gate electrode G1 and the first capacitor electrode CAE1 of the thin-film transistor TFT1 and on the first gate insulating film 131.

A second gate metal layer may be arranged on the second gate insulating film 132. The second gate metal layer may include a second capacitor electrode CAE2. The second capacitor electrode CAE2 may overlap the first capacitor electrode CAE1 of the thin-film transistor TFT1 in the third direction DR3. Because the second gate insulating film 132 has a suitable dielectric constant (e.g., a predetermined dielectric constant), the capacitor (C1 in FIG. 4) may be formed by the first capacitor electrode CAE1, the second capacitor electrode CAE2, and the second gate insulating film 132 arranged between them.

A first interlayer insulating film 141 may be arranged on the second capacitor electrode CAE2 and on the second gate insulating film 132.

A first data metal layer may be arranged on the first interlayer insulating film 141. The first data metal layer may include a first source connection electrode PCE1. The first source connection electrode PCE1 may be connected to the first drain area D1 of the first active layer ACT1 through a first source contact hole PCT1 penetrating the first gate insulating film 131, the second gate insulating film 132, and the interlayer insulating film 141.

A first planarization organic film 160 may be arranged on the first source connection electrode PCE1 and on the first interlayer insulating film 141 to planarize a step caused by the thin-film transistor TFT1.

A second data metal layer may be arranged on the first planarization organic film 160. The second data metal layer may include a second source connection electrode PCE2. The second source connection electrode PCE2 may be connected to the first source connection electrode PCE1 through a second pixel contact hole (PCT2) penetrating the first planarization organic film 160.

A second planarization organic film 180 may be arranged on the second source connection electrode PCE2 and on the first planarization organic film 160.

The barrier film BR, the first gate insulating film 131, the second gate insulating film 132, and the interlayer insulating film 141 may be formed of an inorganic film, such as silicon nitride (SiNₓ), silicon oxide nitride (SiON), silicon oxide (SiOₓ), titanium oxide (TiOₓ), and/or aluminum oxide (AlOₓ).

The first gate metal layer, the second gate metal layer, the first data metal layer, and the second data metal layer may be formed as a single layer or multiple layers of molybdenum (Mo), aluminum (Al), chromium (Cr), gold (Au), titanium (Ti), nickel (Ni), neodymium (Nd), and/or copper (Cu), and/or an alloy thereof.

The first planarization organic film 160 and the second planarization organic film 180 may be formed of an organic film such as an acrylic resin, an epoxy resin, a phenolic resin, a polyamide resin, a polyimide resin, and/or the like.

A light emitting element layer may be arranged on the second planarization organic film 180. The light emitting element layer may include pixel electrodes PXE1, PXE2, and PXE3, light emitting elements LE, a common electrode CE, and an organic partition wall BWL.

A pixel electrode layer and an organic partition wall BWL may be arranged on the second planarization organic film 180. The pixel electrode layer may include a first pixel electrode PXE1, a second pixel electrode PXE2, and a third pixel electrode PXE3. Each of the pixel electrodes PXE1, PXE2, and PXE3 may be connected to a second source connection electrode PCE2 through a connection hole (CT1/CT2/CT3 in FIG. 5) penetrating the second planarization organic film 180. Each of the pixel electrodes PXE1, PXE2, and PXE3 may be connected to a first source area S1 or a first drain area D1 of a thin-film transistor TFT1 through a first source connection electrode PCE1 and a second source connection electrode PCE2. Therefore, a voltage controlled by the thin-film transistor TFT1 may be applied to each of the pixel electrodes PXE1, PXE2, and PXE3.

The pixel electrodes PXE1, PXE2, and PXE3 may be formed as a single layer or multiple layers made of molybdenum (Mo), aluminum (Al), chromium (Cr), gold (Au), titanium (Ti), nickel (Ni), neodymium (Nd), and/or copper (Cu), and/or an alloy thereof. For example, the pixel electrode layer may be made of copper (Cu) having a low surface resistance to lower the resistance of each of the pixel electrodes PXE1, PXE2, and PXE3. Furthermore, the pixel electrodes PXE1, PXE2, and PXE3 may include a first layer made of one or an alloy of molybdenum (Mo), aluminum (Al), chromium (Cr), gold (Au), titanium (Ti), nickel (Ni), neodymium (Nd), and/or copper (Cu) at the bottom when the pixel electrodes PXE1, PXE2, and PXE3 are formed in multiple layers, and a second layer made of a metal material having a high reflectivity, such as aluminum (Al), on the first layer.

The light emitting elements LE may be arranged on the pixel electrodes PXE1, PXE2, and PXE3. For example, a first light emitting element LE1 may be arranged on a first pixel electrode PXE1. A second light emitting element LE2 may be arranged on a second pixel electrode PXE2. A third light emitting element LE3 may be arranged on a third pixel electrode PXE3.

The first light emitting element LE1, the second light emitting element LE2, and the third light emitting element LE3 may emit light of different wavelength bands. For example, the first light emitting element LE1 may emit light of a first wavelength band (e.g., red), the second light emitting element LE2 may emit light of a second wavelength band (e.g., green), and the third light emitting element LE3 may emit light of a third wavelength band (e.g., blue).

On the other hand, the first light emitting element LE1 may be formed of a gallium arsenide (GaAs) based inorganic material, while the second light emitting element LE2 and the third light emitting element LE3 may be formed of a gallium nitride (GaN) based inorganic material. As such, the first light emitting element LE1 may have a structural difference from the other light emitting elements (the second light emitting element LE2 and the third light emitting element LE3) due to the material properties. On the other hand, the second light emitting element LE2 and the third light emitting element LE3 may have the same structure because they are formed of the same gallium nitride (GaN) based inorganic material.

Due to this structural difference, the first light emitting element LE1 may have different heights from one surface to the other surface from the second light emitting element LE2 and the third light emitting element LE3. For example, the height of the first light emitting element LE1 may be higher than (e.g., longer than) the heights of the second light emitting element LE2 and the third light emitting element LE3.

The height difference between the first light emitting element LE1 and other light emitting elements (the second light emitting element LE2 and the third light emitting element LE3) may cause a difference in heat transfer and pressure distribution during the transfer process, which may result in a bonding failure of the first light emitting element LE1. For example, if the height of the first light emitting element LE1 is greater than that of the other light emitting elements (the second light emitting element LE2 and the third light emitting element LE3), there is a high possibility that a relatively greater pressure will be applied during the transfer process. This may cause the first light emitting element LE1 to break, detach from the pixel electrode PXE1, and/or tilt.

To solve this problem, a relatively soft bonding organic pad BOP may be arranged between the first light emitting element LE1 and the first pixel electrode PXE1.

The bonding organic pad BOP may be arranged on one surface of the first pixel electrode PXE1. In one or more embodiments, it may completely overlap one surface of the first pixel electrode PXE1. The bonding organic pad BOP may have an area equal to or smaller than the area of the first pixel electrode PXE1.

In one example, the bonding organic pad BOP may have a rectangular planar shape having a short side equal to the short side of the first pixel electrode PXE1 and a long side equal to the long side of the first pixel electrode PXE1 but is not limited thereto.

The bonding organic pad BOP may include a polymer resin PR and conductive nanoparticles CP dispersed in the polymer resin PR. The polymer resin may be an acrylic resin, a polyimide resin, and/or the like. The conductive nanoparticles CP are conductive particles having a particle size of 100 nm or less. The resistance of the conductive nanoparticles CP is 1 ohm or less.

The conductive nanoparticles CP may be conductive carbon black but is not limited thereto. The conductive nanoparticle CP may include at least one of the first materials selected from the group consisting of acetylene black, artificial graphite, natural graphite, copper powder, nickel powder, aluminum powder, indium powder, silver powder, and polyphenylene in addition to carbon black. The bonding organic pad BOP may be patterned by a photolithography process. Thus, the bonding organic pad BOP may also be finely patterned and thus may be applied to a high-brightness display panel.

The bonding organic pad BOP may be melted at less than 200 degrees, for example, 140 degrees, to bond the first light emitting element LE1 onto the first pixel electrode PXE1.

The bonding organic pad BOP may be a distance (e.g., a thickness) h-OBP from the interface between the bonding organic pad BOP and the first pixel electrode PXE1 to the interface between the bonding organic pad BOP and the first light emitting element LE1, i.e., the height of the bonding organic pad BOP may be about 1 μm or less. When the height of the bonding organic pad BOP is greater than 1 μm, the electrical conductivity may be reduced.

Because the bonding organic pad BOP includes a conductive nanoparticle CP, the first pixel electrode PXE1 and the first light emitting element LE1 may be electrically connected.

Therefore, the first light emitting elements LE1 may be bonded and electrically connected to the first pixel electrode PXE1 by the bonding organic pad BOP.

A bonding metal pad BMP may be further arranged between the bonding organic pad BOP and the first light emitting element LE1. The bonding metal pad BMP may include, for example, gold (Au), a metal that is not easily oxidized and has high conductivity.

On the other hand, a bottom bonding electrode BBE is arranged between the second light emitting element LE2 and the second pixel electrode PXE2. A bottom bonding electrode BBE is arranged between the third light emitting element LE3 and the third pixel electrode PXE3. Because the bottom bonding electrode BBE arranged between the second light emitting element LE2 and the second pixel electrode PXE2 and the bottom bonding electrode BBE arranged between the third light emitting element LE3 and the third pixel electrode PXE3 are substantially made of the same material and structure, the bottom bonding electrode BBE arranged between the second light emitting element LE2 and the second pixel electrode PXE2 will be described as one example.

A bottom bonding electrode BBE may be arranged on the second pixel electrode PXE2, and an upper bonding electrode UBE may be arranged on the bottom bonding electrode BBE. The bottom bonding electrode BBE and the upper bonding electrode UBE may be melted and bonded by heat and pressure and may be electrically connected to each other. A bottom bonding electrode BBE may be arranged on the third pixel electrode PXE3, and an upper bonding electrode UBE may be arranged on the bottom bonding electrode BBE.

The first light emitting element LE1, the second light emitting element LE2, and the third light emitting element LE3 may have a length in the first direction DR1, a length in the second direction DR2, and a length in the third direction DR3 of approximately 6 μm to 10 μm or less, respectively. The length in the third direction DR3 may be referred to as a height or thickness.

Each of the first light emitting element LE1, the second light emitting element LE2, and the third light emitting element LE3 may be formed by growing on a semiconductor substrate such as a silicon substrate or a sapphire substrate. Each of the first light emitting element LE1, the second light emitting element LE2, and the third light emitting element LE3 may be transferred directly from the semiconductor substrate onto the pixel electrodes PXE1, PXE2, and PXE3 of the display panel 100. Alternatively, each of the first light emitting element LE1, the second light emitting element LE2, and the third light emitting element LE3 may be transferred onto the pixel electrodes PXE1, PXE2, and PXE3 of the display panel 100 by an electrostatic method using an electrostatic head or a stamp method using an elastic polymer material such as PDMS or silicon as a transfer substrate. For example, a plurality of first light emitting elements LE1 may be first transferred to the first pixel electrodes PXE1, then a plurality of second light emitting elements LE2 may be transferred to the second pixel electrodes PXE2, and a plurality of third light emitting elements LE3 may be transferred to the third pixel electrodes PXE3.

The first light emitting element LE1, the second light emitting element LE2, and the third light emitting element LE3 may include a conductive layer E1, a first semiconductor layer SEM1, an active layer MQW, a second semiconductor layer SEM2, a contact electrode CTE, and a protective film INS.

The conductive layer E1 may be arranged on the bottom surface of the first semiconductor layer SEM1. In FIG. 7, the conductive layer E1 is illustrated covering the entire underside of the first semiconductor layer SEM1, but the present disclosure is not limited thereto. For example, the conductive layer E1 may be arranged on a portion of the bottom surface of the first semiconductor layer SEM1. The conductive layer E1 may include molybdenum (Mo), aluminum (Al), chromium (Cr), gold (Au), titanium (Ti), nickel (Ni), neodymium (Nd), and/or copper (Cu).

The first semiconductor layer SEM1 may be arranged on the conductive layer E1. The first semiconductor layer SEM1 may be formed of a semiconductor material layer doped with a first-conductivity dopant such as magnesium (Mg), zinc (Zn), calcium (Ca), strontium (Sr), barium (Ba), and/or the like, such as gallium nitride (GaN).

The active layer MQW may be arranged on the first semiconductor layer SEM1. The active layer MQW may emit light by combining electron-hole pairs according to an electrical signal applied through the first semiconductor layer SEM1 and the second semiconductor layer SEM2.

The active layer MQW may include a material having a single or multi-quantum well structure. When the active layer MQW includes a material having a multi-quantum well structure, it may have a structure in which a plurality of well layers and barrier layers are alternately stacked. At this time, the well layer may be formed of indium gallium nitride (InGaN), and the barrier layer may be formed of gallium nitride (GaN) and/or aluminum gallium nitride (AlGaN), but the present disclosure are not limited thereto.

Alternatively, the active layer MQW may have a structure in which semiconductor materials having a high band gap energy and semiconductor materials having a low band gap energy are alternately stacked with each other, may include other Group III to Group V semiconductor materials according to the wavelength range of emitted light.

In one or more embodiments, when the active layer MQW includes InGaN, the color of the emitted light may vary depending on the content of indium (In). For example, as the content of indium (In) increases, the wavelength band of light emitted by the active layer may shift to the red wavelength band, and as the content of indium (In) decreases, the wavelength band of light emitted by the active layer may shift to the blue wavelength band. For example, the content of indium (In) in the active layer MQW of the light emitting element LE that emits the third light (e.g., light in the blue wavelength band) may be approximately 10 wt% to 20 wt%.

The second semiconductor layer SEM2 may be arranged on the active layer MQW. The second semiconductor layer SEM2 may be a semiconductor material layer doped with a second conductive dopant such as silicon (Si), germanium (Ge), tin (Sn), and/or the like, for example gallium nitride (GaN).

An electron blocking layer may be arranged between the first semiconductor layer SEM1 and the active layer MQW. The electron blocking layer may be a layer to suppress or prevent too many electrons from flowing into the active layer MQW. For example, the electron blocking layer may be aluminum gallium nitride (AlGaN) or p-type aluminum gallium nitride (AlGaN) doped with p-type magnesium (Mg). The electronic blocking layer may be omitted.

A superlattice layer may be arranged between the active layer MQW and the second semiconductor layer SEM2. The superlattice layer may be a layer for relieving stress between the second semiconductor layer SEM2 and the active layer MQW. For example, the superlattice layer may be aluminum gallium nitride (AlGaN) or p-type aluminum gallium nitride (AlGaN) doped with p-type magnesium (Mg). The superlattice layer may be omitted.

The second light emitting element LE2 and the third light emitting element LE3 may include light extraction patterns LEP on their top surfaces. For example, the light extraction patterns LEP may be formed on the top surface of the second semiconductor layer SEM2.

The light extraction patterns LEP may be patterns for increasing the efficiency of light emitted from the top surfaces of the second light emitting element LE2 and the third light emitting element LE3. The light extraction patterns LEP may be concave patterns formed in a hemisphere or a semi-ellipse. The light extraction patterns LEP may be concave patterns having a cross-sectional shape of a semicircle or a semi-ellipse.

The protective film INS may be a film for protecting the bottom surface and the side surface of the light emitting element LE. The protective film INS may be arranged on the bottom surface and the side surface of the conductive layer E1 and the side surface of the semiconductor layer. Specifically, the protective film INS may be arranged on the bottom surface and side surface of the conductive layer E1, the side surface of the first semiconductor layer SEM1, the side surface of the active layer MQW, and the side surface of the second semiconductor layer SEM2. The protective film INS may be formed of an inorganic film, such as silicon nitride (SiNₓ), silicon oxide nitride (SiON), silicon oxide (SiOₓ), titanium oxide (TiOₓ), and/or aluminum oxide (AlOₓ).

The contact electrode CTE may be arranged on the protective film INS. The contact electrode CTE may be arranged between the pixel electrodes PXE1, PXE2, and PXE3 and the protective film INS. The contact electrode CTE may be in contact with the pixel electrodes PXE1, PXE2, and PXE3.

The contact electrode CTE may be connected to the conductive layer E1 that is exposed and not covered by the protective film INS.

The contact electrode CTE may include indium (In), bismuth (Bi), molybdenum (Mo), aluminum (Al), chromium (Cr), gold (Au), titanium (Ti), nickel (Ni), neodymium (Nd), copper (Cu), and/or SAC (tin-silver-copper alloy (Sn-Ag-Cu)). Specifically, the plurality of contact electrodes CTE may be formed as a two-layer structure of chromium (Cr) and gold (Au), a three-layer structure of titanium (Ti), aluminum (Al), and titanium (Ti), or a three-layer structure of indium tin oxide (ITO), silver (Ag), and indium tin oxide (ITO) to increase reflectivity.

The second organic layer 211 may be arranged to cover the side surfaces of the plurality of light emitting elements LE.

The second organic layer 211 is a layer for flattening the steps caused by the plurality of light emitting elements LE. The height of the second organic layer 211 may be arranged to cover most of the side surfaces of each of the plurality of light emitting elements LE, but in another embodiment, the second organic layer 211 may be arranged to cover the side surfaces of each of the plurality of light emitting elements LE by a plurality of organic films.

The second organic layer 211 may be formed of an organic film such as an acrylic resin, an epoxy resin, a phenolic resin, a polyamide resin, and/or a polyimide resin.

The common electrode CE may be arranged on the top surface of each of the plurality of light emitting elements LE and the top surface of the second organic layer 211.

The common electrode CE may be a common layer formed commonly on the first sub-pixel SPX1, the second sub-pixel SPX2, and the third sub-pixel SPX3. For example, the common electrode CE may be arranged on the first light emitting element LE1, the second light emitting element LE2, and the third light emitting element LE3. The common electrode CE may be made of a transparent conductive material (TCO) such as indium tin oxide (ITO) and/or indium zinc oxide (IZO) that may transmit light.

The pixel electrodes PXE1, PXE2, and PXE3 may be referred to as an anode electrode or a first electrode, and the common electrode CE may be referred to as a cathode electrode or a second electrode.

A first capping layer CAP1 may be arranged on the common electrode CE. The first capping layer CAP1 may serve to encapsulate the underlying component.

The first capping layer CAP1 may be formed of an inorganic film, such as silicon nitride (SiNₓ), silicon oxide nitride (SiON), silicon oxide (SiOₓ), titanium oxide (TiOₓ), and/or aluminum oxide (AlOₓ).

A third organic layer 213 may be arranged on the first capping layer CAP1. A plurality of color filters CF1, CF2, and CF3 may be arranged on the third organic layer 213. The plurality of color filters CF1, CF2, and CF3 may include first color filters CF1, second color filters CF2, and third color filters CF3.

The first color filter CF1 arranged in the first sub-pixel SPX1 may transmit the first light (e.g., light in the red wavelength band). Therefore, the first sub-pixel SPX1 may emit the first light (e.g., light in the red wavelength band).

The second color filter CF2 arranged in the second sub-pixel SPX2 may transmit the second light (e.g., light in the green wavelength band). Therefore, the second sub-pixel SPX2 may emit the second light (e.g., light in the green wavelength band).

The third color filter CF3 arranged in the third sub-pixel SPX3 may transmit the third light (e.g., light of a blue wavelength band). Therefore, the third sub-pixel SPX3 may emit the third light (e.g., light of a blue wavelength band).

The first color filter CF1, the second color filter CF2, and the third color filter CF3 overlapping in the third direction DR3 may overlap the organic partition wall BWL in the third direction DR3. In another embodiment, the first color filter CF1, the second color filter CF2, and the third color filter CF3 may be omitted.

A fourth organic layer 214 for planarization may be arranged on the plurality of color filters CF1, CF2, and CF3.

The third organic layer 213 and the fourth organic layer 214 may be formed from an acrylic resin, an epoxy resin, a phenolic resin, a polyamide resin, a polyimide resin, or the like.

Referring to FIG. 8, the first light emitting element LE1 may be bonded to the first pixel electrode PXE1 by a bonding organic pad BOP and a bonding metal pad BMP and may be electrically connected.

The second light emitting element LE2 may be bonded to the second pixel electrode PXE2 by a bottom bonding electrode BBE and an upper bonding electrode UBE and may be electrically connected.

The height of the first light emitting element LE1 may be different from the height of the second light emitting element LE2. For example, the height h-LE1 of the first light emitting element LE1 may be higher than (e.g., longer than) the height h-LE2 of the second light emitting element LE2. The height h-LE1 of the first light emitting element LE1 is the height from the bottom surface to the top surface of the first light emitting element LE1, where the bottom surface of the first light emitting element LE1 is an interface between the first light emitting element LE1 and the bonding metal pad BMP, and the top surface may be a surface facing the bottom surface (e.g., a surface opposite the bottom surface). The height h-LE2 of the second light emitting element LE2 is the height from the bottom surface to the top surface of the second light emitting element LE2, where the bottom surface of the second light emitting element LE2 is an interface between the second light emitting element LE2 and the upper bonding electrode UBE, and the top surface may be a surface facing the bottom surface (e.g., a surface opposite the bottom surface).

The distance h-S1 from the interface of the first pixel electrode PXE1 and the bonding organic pad BOP to the top surface of the first light emitting element LE1 is the same as the distance h-S2 from the interface of the second pixel electrode PXE2 and the bottom bonding electrode BBE to the top surface of the second light emitting element LE2. Thus, the top surface of the first light emitting element LE1 and the top surface of the second light emitting element LE2 may be arranged on the same plane.

The distance h-S1 from the interface of the first pixel electrode PXE1 and the bonding organic pad BOP to the top surface of the first light emitting element LE1 is the sum of the height h-LE1 of the first light emitting element LE1, the height of the bonding metal pad BMP, and the height of the bonding organic pad BOP. The height may be a distance in the third direction DR3.

The distance h-S2 from the interface of the second pixel electrode PXE2 and the bottom bonding electrode BBE to the top surface of the second light emitting element LE2 is the sum of the height h-LE2 of the second light emitting element LE2, the height of the bottom bonding electrode BBE, and the height of the upper bonding electrode UBE.

The top surface of the first light emitting element LE1 may be flat because it does not include a light extraction pattern LEP. On the other hand, the top surface of the second light emitting element LE2 may include a light extraction pattern LEP having a semicircular or semi-elliptical cross-sectional shape but is not limited thereto.

The bonding organic pad BOP and the bottom bonding electrode BBE may include different materials. The bonding organic pad BOP includes an organic material, and the bottom bonding electrode BBE includes a metal material.

The bonding organic pad BOP may include a polymer resin, and conductive nanoparticles dispersed in the polymer resin. The conductive nanoparticles may be conductive carbon black.

The bottom bonding electrode BBE may be a metal electrode including copper or indium, etc.

The height of the bonding organic pad BOP may be 1 μm or less, and the height of the bottom bonding electrode BBE may be greater than 1 μm.

The bonding metal pad BMP and the upper bonding electrode UBE may be made of different materials. For example, the bonding metal pad BMP may include a metal having higher conductivity than the upper bonding electrode UBE. Further, the bonding metal pad BMP may include a metal that is less easily oxidized than the upper bonding electrode UBE.

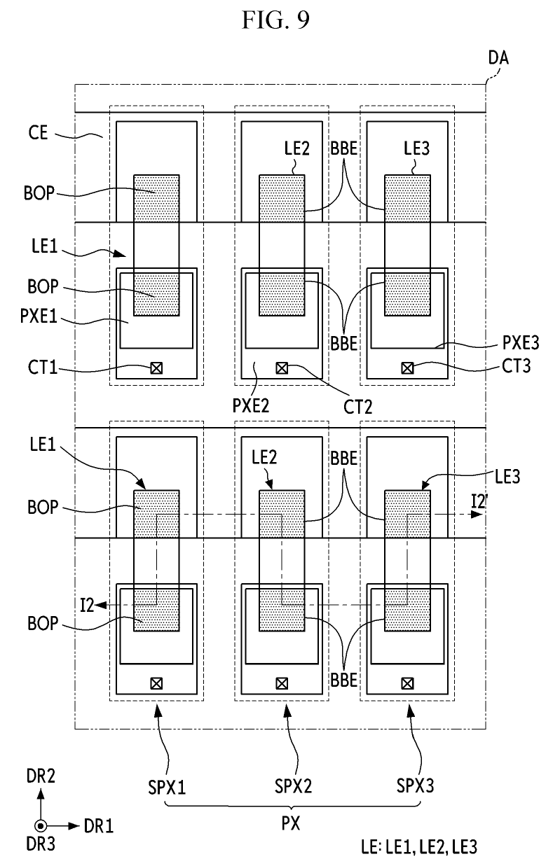

FIG. 9 is a layout diagram illustrating pixels of a display area according to one or more embodiments.

The embodiment of FIG. 9 differs from the embodiment of FIGS. 5–6 in that the light emitting element LE is arranged on the pixel electrodes PXE1, PXE2, and PXE3 and the common electrode CE in each of the first sub-pixel SPX1, the second sub-pixel SPX2, and the third sub-pixel SPX3. In FIG. 9, descriptions that overlap with the embodiment of FIG. 6 will be omitted, and differences from the embodiment of FIG. 6 will be mainly described.

Referring to FIG. 9, a first sub-pixel SPX1 may include a first pixel electrode PXE1, a common electrode CE, a first light emitting element LE1, and a bonding organic pad BOP. A second sub-pixel SPX2 may include a second pixel electrode PXE2, a common electrode CE, a second light emitting element LE2, and a bottom bonding electrode BBE. A third sub-pixel SPX3 may include a third pixel electrode PXE3, a common electrode CE, a third light emitting element LE3, and a bottom bonding electrode BBE.

The pixel electrodes PXE1, PXE2, and PXE3 and the common electrode CE in each of the first sub-pixel SPX1, the second sub-pixel SPX2, and the third sub-pixel SPX3 may be arranged along the second direction DR2. Each of the pixel electrodes PXE1, PXE2, and PXE3 and the common electrodes CE may have a rectangular planar shape, but the present disclosure is not limited thereto.

The common electrode CE may be connected to a second power supply line VSL to which a second driving voltage VSS is applied. Thus, the second driving voltage VSS may be applied to each of the common electrodes CE.

In each of the first sub-pixel SPX1, the second sub-pixel SPX2, and the third sub-pixel SPX3, the light emitting elements LE are arranged on the pixel electrodes PXE1, PXE2, and PXE3 and the common electrode CE, so that the length of the light emitting element LE in the second direction DR2 may be longer than the length in the first direction DR1.

The bonding organic pad BOP may be arranged on the first pixel electrode PXE1 and the common electrode CE of the first sub-pixel SPX1, and the bottom bonding electrode BBE may be arranged on the second pixel electrode PXE2, the third pixel electrode PXE3, and the common electrode CE of the second sub-pixel SPX2 and the third sub-pixel SPX3. Each of the bonding organic pad BOP and the bottom bonding electrode BBE may have a rectangular planar shape.

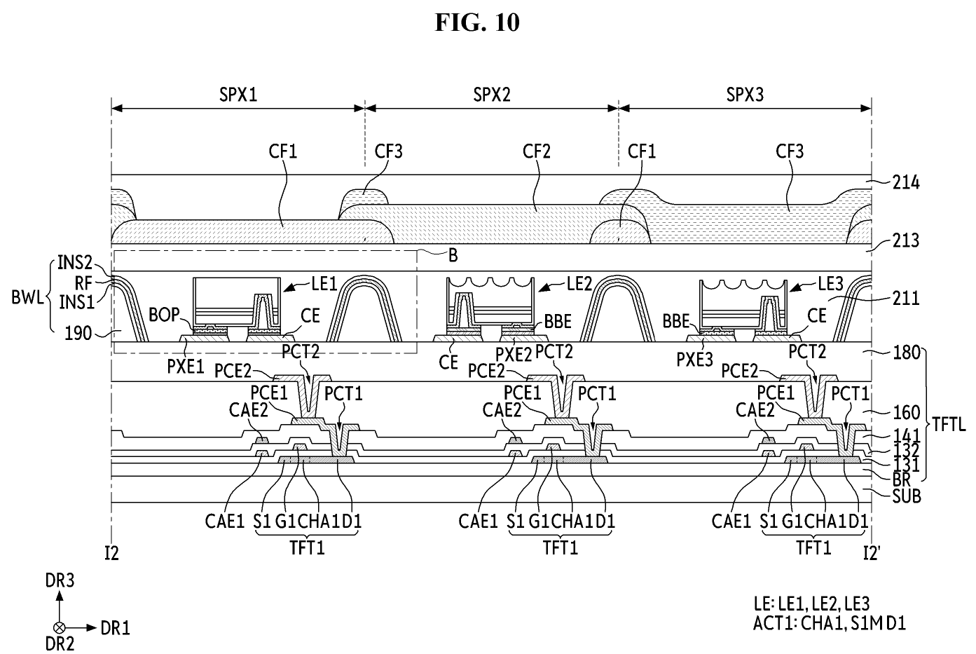

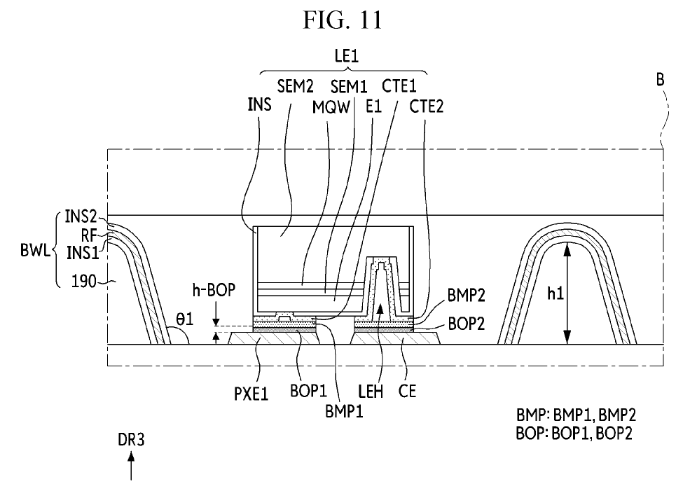

FIG. 10 is a cross-sectional view illustrating one example of a cross-section of a display panel corresponding to the line I2-I2' of FIG. 9. FIG. 11 is a cross-sectional view illustrating in detail one example of an area B of FIG. 10.

The embodiments of FIGS. 10 and 11 differ from the embodiments of FIGS. 6 and 7 in that the light emitting element LE is a flip-type micro LED. In FIGS. 10 and 11, descriptions that overlap with the embodiments of FIGS. 6 and 7 will be omitted, and differences from the embodiments of FIGS. 6 and 7 will be mainly described.

Referring to FIGS. 10 and 11, a pixel electrode layer including pixel electrodes PXE1, PXE2, and PXE3 and a common electrode CE may be arranged on a second planarization organic film 180.

The light emitting element LE may be a flip-type micro LED. The flip-type micro LED refers to an LED in which contact electrodes CTE1 and CTE2 are formed on one surface (e.g., the bottom surface) of the light emitting element LE. The length of the third direction DR3 of the plurality of light emitting elements LE may be approximately 3 μm to 5 μm or less but is not limited thereto.

While FIG. 11 illustrates an example where the protective film INS is arranged on bottom surface and side surface of the conductive layer E1, the sides of the first semiconductor layer SEM1, the sides of the active layer MQW, and the sides of the second semiconductor layer SEM2, the present disclosure is not limited thereto. In one example, the protective film INS may be arranged on side surfaces of the first semiconductor layer SEM1, side surfaces of the active layer MQW, and side surfaces of the second semiconductor layer SEM2 of the semiconductor stack STC including the first semiconductor layer SEM1, the active layer MQW, and the second semiconductor layer SEM2.

The plurality of light emitting elements LE may be arranged on the pixel electrodes PXE1, PXE2, and PXE3 and the common electrode CE.

A first contact electrode CTE1 may be arranged on the pixel electrodes PXE1, PXE2, and PXE3, and a second contact electrode CTE2 may be arranged on the common electrode CE.

A hole LEH may be formed to penetrate the conductive layer E1, the first semiconductor layer SEM1, and the active layer MQW of the light emitting element LE to expose the second semiconductor layer SEM2. The hole LEH may have a circular planar shape, but the present disclosure is not limited thereto. For example, the hole LEH may have a polygonal planar shape, such as an oval or a square. The conductive layer E1, the first semiconductor layer SEM1, the active layer MQW, and the second semiconductor layer SEM2 of the first light emitting element LE1 have been described with reference to FIGS. 6 and 7, and thus detailed descriptions thereof will not be repeated. The conductive layer E1, the first semiconductor layer SEM1, the active layer MQW, and the second semiconductor layer SEM2 of the second light emitting element LE2 and the third light emitting element LE3 have been described with reference to FIGS. 6 and 7, and thus detailed descriptions thereof will not be repeated.

In addition, the protective film INS may be arranged on the sidewall of the conductive layer E1 exposed in the hole LEH, the sidewall of the first semiconductor layer SEM1, the sidewall of the active layer MQW, and the sidewall of the second semiconductor layer SEM2. The protective film INS may not cover the second semiconductor layer SEM2 in the hole LEH.

The first contact electrode CTE1 may be arranged on one surface of the conductive layer E1. Thus, the first contact electrode CTE1 may be electrically connected to the conductive layer E1 that is exposed and not covered by the protective layer INS.

The second contact electrode CTE2 may be arranged on one surface of the conductive layer E1 spaced (e.g., spaced apart) from the first contact electrode CTE1. The second contact electrode CTE2 may be arranged on the protective film INS arranged in the hole LEH and the second semiconductor layer SEM2 exposed in the hole LEH without being covered by the protective film INS. Thus, the second contact electrode CTE2 may be electrically connected to the second semiconductor layer SEM2 in the hole LEH. The first contact electrode CTE1 and the second contact electrode CTE2 may include indium (In), bismuth (Bi), molybdenum (Mo), aluminum (Al), chromium (Cr), gold (Au), titanium (Ti), nickel (Ni), neodymium (Nd), copper (Cu), and/or a tin-silver-copper alloy (Sn-Ag-Cu) (SAC). Specifically, the first contact electrode CTE1 and the second contact electrode CTE2 may be formed from a two-layer structure of chromium (Cr) and gold (Au), a three-layer structure of titanium (Ti), aluminum (Al), and titanium (Ti), or a three-layer structure of indium tin oxide (ITO), silver (Ag), and indium tin oxide (ITO) to increase reflectivity.

A first bonding organic pad BOP1 may be arranged on a first pixel electrode PXE1 of a first sub-pixel SPX1, and a first bonding metal pad BMP1 may be arranged on the first bonding organic pad BOP1. A second bonding organic pad BOP2 may be arranged on a common electrode CE1 of the first sub-pixel SPX1, and a second bonding metal pad BMP2 may be arranged on the second bonding organic pad BOP2.

In addition, the first contact electrode CTE1 of the first light emitting element LE1 may be arranged on the first bonding metal pad BMP1. The first bonding metal pad BMP1 may be electrically connected to the first contact electrode CTE1 of the first light emitting element LE1.

The second bonding metal pad BMP2 may be arranged on a portion of second bonding organic pad BOP2 arranged on one surface of the common electrode CE1. Also, the second contact electrode CTE2 of the first light emitting element LE1 may be arranged on the second bonding metal pad BMP2. The second bonding metal pad BMP2 may be electrically connected to the second contact electrode CTE2 of the first light emitting element LE1.

A thickness (height) of the first bonding organic pad BOP1 and a thickness (height) of the second bonding organic pad BOP1, that is, the distance h-BOP between the interface with the first pixel electrode PXE1 (or the common electrode CE) and the interface with the first bonding metal pad BMP1 or the second bonding metal pad BMP2 is about 1 μm or less.

An organic partition wall BWL may be formed on the second planarization organic film 180 with a first inclination angle θ1 and a first height h1.

The first inclination angle θ1 may be 120 degrees or more. Preferably, the first inclination angle θ1 may be about 120 degrees to 135 degrees. The first height h1 may be about 5 μm to 6 μm.

The organic partition wall BWL may include a first organic layer 190 defining the shape of the organic partition wall BWL, a first protective film INS1 covering the first organic layer 190, a reflective film RF on the first protective film INS1, and a second protective film INS2 on the reflective film RF.

The reflective film RF is arranged outside the first protective film INS1. The second protective film INS2 is arranged outside the reflective film RF. The reflective film RF is surrounded by the first protective film INS1 and the second protective film INS2.

The reflective film RF may have a closed loop shape that surrounds the side of the light emitting element LE while being spaced (e.g., spaced apart) from the light emitting element LE on a plane. The upper portion of the reflective film RF may be arranged higher than the active layer MQW of the light emitting element LE. The lower portion of the reflective film RF may be positioned lower than the light emitting element LE. The reflective film RF may include a metal material having a high reflectivity, such as aluminum (Al).

A vertical distance (height) from the uppermost portion to the lowermost portion of the reflective film RF is 80% to 120% of the height of the light emitting element LE. When the reflective film RF is formed higher than the height of the light emitting element LE, there is an advantage in terms of light emission efficiency. On the other hand, when the reflective film RF is formed lower than the height of the light emitting element LE, there is an advantage in that the light emitting element LE is easily transferred.

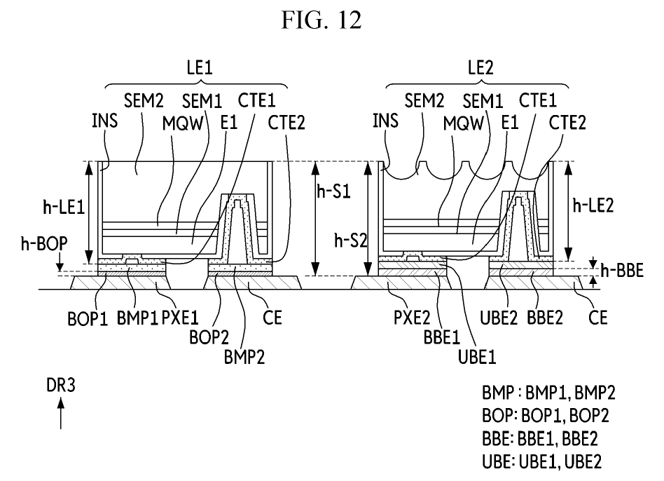

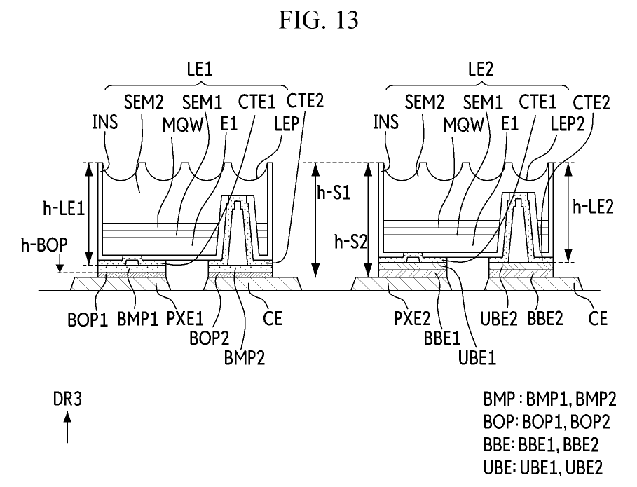

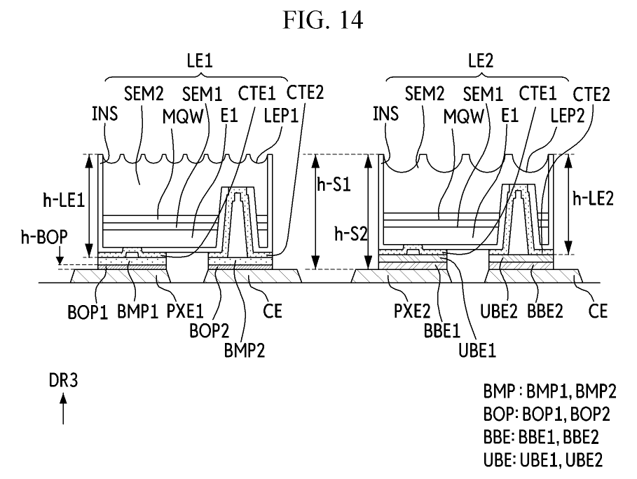

FIG. 12 is a cross-sectional view illustrating in detail one example of the bonding structure of the first pixel electrode and the first light emitting element of FIG. 10 and the bonding structure of the second pixel electrode and the second light emitting element of FIG. 10. FIGS. 13 and 14 are cross-sectional views illustrating another embodiment of the first light emitting element of FIG. 12.

Referring to FIG. 12, the first light emitting element LE1 may be bonded and electrically connected to the first pixel electrode PXE1 by a first bonding organic pad BOP1 and a first bonding metal pad BMP1 and may be bonded and electrically connected to the common electrode CE by a second bonding organic pad BOP2 and a second bonding metal pad BMP2.

The second light emitting element LE2 may be bonded and electrically connected to the second pixel electrode PXE2 by the first bottom bonding electrode BBE1 and the first upper bonding electrode UBE1 and may be bonded and electrically connected to the common electrode CE by the second bottom bonding electrode BBE2 and the second upper bonding electrode UBE2.

A height of the first light emitting element LE1 may be different from a height of the second light emitting element LE2. For example, the height h-LE1 of the first light emitting element LE1 may be higher than (e.g., longer than) the height h-LE2 of the second light emitting element LE2. The height h-LE1 of the first light emitting element LE1 is the height from the bottom surface to the top surface of the first light emitting element LE1, where the bottom surface of the first light emitting element LE1 is an interface between the first light emitting element LE1 and the bonding metal pad BMP, and the top surface may be a surface facing the bottom surface (e.g., a surface opposite the bottom surface). The height h-LE2 of the second light emitting element LE2 is the height from the bottom surface to the top surface of the second light emitting element LE2, where the bottom surface of the second light emitting element LE2 is an interface between the second light emitting element LE2 and the upper bonding electrode UBE, and the top surface may be a surface facing the bottom surface (e.g., a surface opposite the bottom surface).

The distance h-S1 from the interface of the first pixel electrode PXE1 and the bonding organic pad BOP to the top surface of the first light emitting element LE1 is the same as the distance h-S2 from the interface of the second pixel electrode PXE2 and the bottom bonding electrode BBE to the top surface of the second light emitting element LE2. Thus, the top surface of the first light emitting element LE1 and the top surface of the second light emitting element LE2 may be arranged on the same plane.

The distance h-S1 from the interface of the first pixel electrode PXE1 and the bonding organic pad BOP to the top surface of the first light emitting element LE1 is the sum of the height h-LE1 of the first light emitting element LE1, the height of the bonding metal pad BMP, and the height of the bonding organic pad BOP. The height may be a distance in the third direction DR3.

The distance h-S2 from the interface of the second pixel electrode PXE2 and the bottom bonding electrode BBE to the top surface of the second light emitting element LE2 is the sum of the height h-LE2 of the second light emitting element LE2, the height of the bottom bonding electrode BBE, and the height of the upper bonding electrode UBE.

The top surface of the first light emitting element LE1 may be flat because it does not include a light extraction pattern LEP. On the other hand, the top surface of the second light emitting element LE2 may include a light extraction pattern LEP having a semicircular or semi-elliptical cross-sectional shape but is not limited thereto. For example, as shown in FIGS. 13 and 14, the top surface of the first light emitting element LE1 may include a light extraction pattern LEP. As shown in FIG. 13, the shape and roughness of the light extraction pattern LEP of the top surface of the first light emitting element LE1 and the light extraction pattern LEP of the top surface of the second light emitting element LE2 may be the same. The deviation of the unevenness of the light extraction pattern LEP on the top surface of the first light emitting element LE1 and the deviation of the unevenness of the light extraction pattern LEP on the top surface of the second light emitting element LE2 may be the same.

As shown in FIG. 14, the deviation of the unevenness of the light extraction pattern LEP1 of the top surface of the first light emitting element LE1 may be different from the deviation of the unevenness of the light extraction pattern LEP2 of the second light emitting element LE2. For example, the deviation of the unevenness of the light extraction pattern LEP2 of the top surface of the second light emitting element LE2 may be smaller than the deviation of the unevenness of the light extraction pattern LEP1 of the first light emitting element LE1. A smaller deviation in the unevenness may indicate a shallower depth of the unevenness.

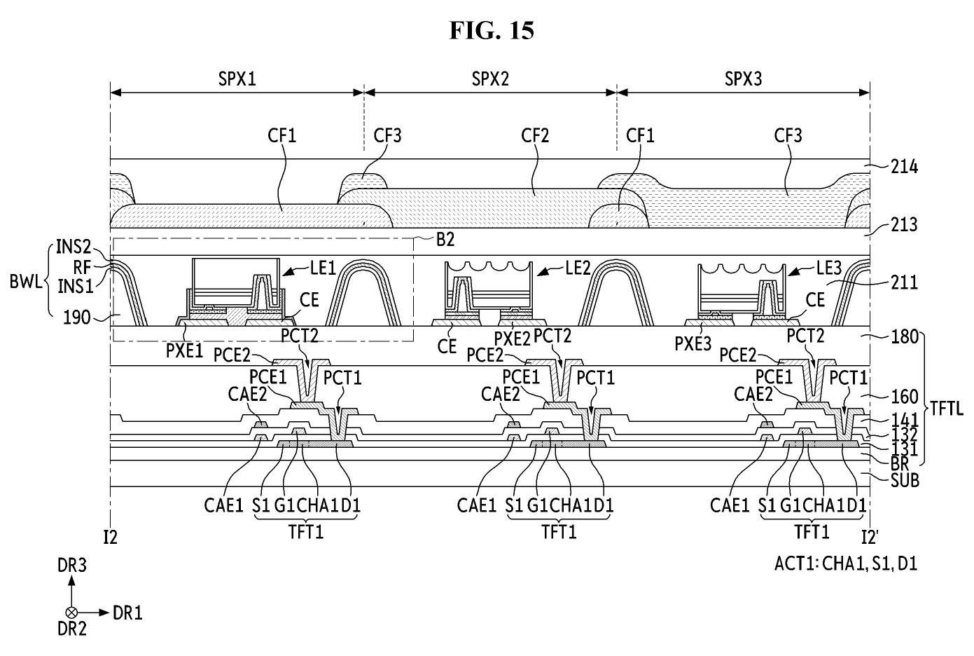

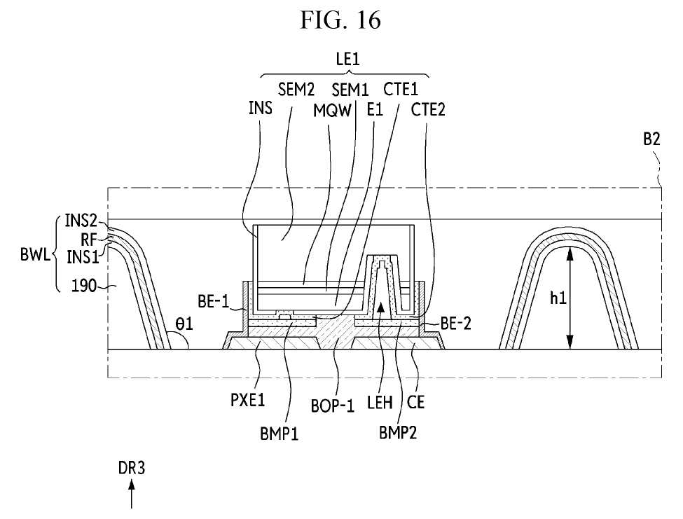

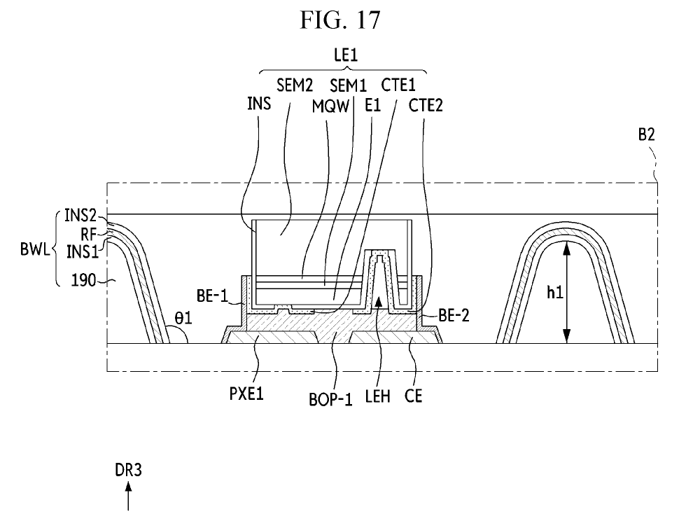

FIG. 15 is a cross-sectional view illustrating one example of a cross-section of a display panel corresponding to the line I2-I2' of FIG. 9 according to another embodiment. FIG. 16 is a cross-sectional view illustrating one example of an area B2 of FIG. 15 in detail. FIG. 17 is a cross-sectional view illustrating one example of the area B2 of FIG. 15 in detail according to one or more embodiments.

The embodiments of FIGS. 15 and 16 differ from the embodiments of FIGS. 10 and 11 in that the bonding organic pad BOP-1 on the first sub-pixel SPX1 includes a non-conductive organic material, the first light emitting element LE1 and the first pixel electrode PXE1 are electrically connected by the first connection electrode BE-1, and the first light emitting element LE1 and the common electrode CE are electrically connected by the second connection electrode BE-2. In FIGS. 15 and 16, descriptions that overlap with the embodiments of FIGS. 10 and 11 will be omitted, and differences from the embodiments of FIGS. 10 and 11 will be mainly described.

Referring to FIGS. 15 and 16, a pixel electrode layer including pixel electrodes PXE1, PXE2, and PXE3 and a common electrode CE may be arranged on a second planarization organic film 180.

A non-conductive bonding organic pad BOP-1 may be arranged on the first pixel electrode PXE1 and the common electrode CE. The non-conductive bonding organic pad BOP-1 exposes at least a portion of the first pixel electrode PXE1 and exposes at least a portion of the common electrode CE.

The bonding organic pad BOP-1 in the embodiment of FIGS. 15 and 16 may be referred to as a non-conductive bonding organic pad BOP-1 to distinguish it from the bonding organic pad BOP of the embodiment described with reference to FIGS. 10 – 14.

The non-conductive bonding organic pad BOP-1 temporarily fixes or adheres an upper member (e.g., a first light emitting element LE1). For example, the non-conductive bonding organic pad BOP-1 may be a film for pseudo-adhesion an upper member (e.g., a first light emitting element LE1) onto each of the first pixel electrodes PXE1 and the common electrode CE. To facilitate pseudo-adhesion, the thickness of the non-conductive bonding organic pad BOP-1 may be greater than the thickness of each of the first pixel electrodes PXE1 and the common electrode CE and may be greater than the thickness of the contact electrode CTE.

The non-conductive bonding organic pad BOP-1 may be formed of an acrylic resin, an epoxy resin, a phenolic resin, a polyamide resin, a polyimide resin, and/or the like.

The first light emitting elements LE1 may be arranged on the non-conductive bonding organic pad BOP-1. The first light emitting elements LE1 differ from the first light emitting elements LE1 of FIGS. 10-14 in that the first contact electrode CTE1 and the second contact electrode CTE2 may be arranged on the side and bottom surfaces of the semiconductor layer. In FIGS. 15 and 16, overlapping descriptions with the embodiments of FIGS. 10-14 will be omitted, and differences from the embodiments of FIGS. 10-14 will be mainly described.

The first contact electrode CTE1 and the second contact electrode CTE2 in FIGS. 15 and 16 may be arranged on one side and the side surfaces of the semiconductor layer.

The first contact electrode CTE1 may be arranged on the bottom surface of the conductive layer E1 that is exposed and not covered by the protective film INS. Thus, the first contact electrode CTE1 may be electrically connected to the conductive layer E1.

The second contact electrode CTE2 may be arranged on the protective film INS disposed in the hole LEH and the second semiconductor layer SEM2 exposed without being covered by the protective film INS in the hole LEH. Therefore, the second contact electrode CTE2 may be electrically connected to the second semiconductor layer SEM2 in the hole LEH.

Each of the first contact electrode CTE1 and the second contact electrode CTE2 may be arranged on three side surfaces of the semiconductor layer. For example, when the semiconductor layer includes first to fourth side surfaces, the first contact electrode CTE1 may be arranged on the first side surface, the second side surface, and the third side surface, and the second contact electrode CTE2 may be arranged on the second side surface, the third side surface, and the fourth side surface.

The first connection electrode BE-1 connects the first contact electrode CTE1 of the first light emitting element LE1 and the first pixel electrode PXE1. The first connection electrode BE-1 is arranged on a top surface of the first pixel electrode PXE1 that is exposed and not covered by the non-conductive bonding organic pad BOP-1 and may contact the outer side of the first contact electrode CTE1 along the side surface and the top surface of the non-conductive bonding organic pad BOP-1. Further, the second connection electrode BE-2 connects the second contact electrode CTE2 of the second light emitting element LE2 and the common electrode CE. The second connection electrode BE-2 is arranged on a top surface of the common electrode CE that is exposed and not covered by the non-conductive bonding organic pad BOP-1 and may contact the outer side of the second contact electrode CTE2 along the side surface and the top surface of the non-conductive bonding organic pad BOP-1.

The first connection electrode BE-1 and the second connection electrode BE-2 may include -molybdenum (Mo), aluminum (Al), chromium (Cr), gold (Au), titanium (Ti), nickel (Ni), neodymium (Nd), and/or copper (Cu). Alternatively, the first connection electrode BE-1 and the second connection electrode BE-2 may be made of a transparent conductive material (TCO), such as indium tin oxide (ITO) and/or indium zinc oxide (IZO).

As shown in FIG. 16, bonding metal pads BMP1 and BMP2 may be arranged between the non-conductive bonding organic pad BOP-1 and the first light emitting element LE1. In another embodiment, as shown in FIG. 17, the bonding metal pads BMP1 and BMP2 may be omitted between the non-conductive bonding organic pad BOP-1 and the first light emitting element LE1.

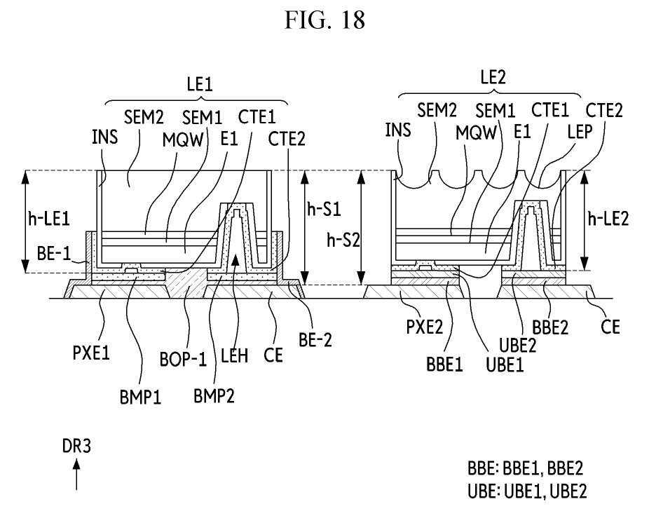

FIG. 18 is a cross-sectional view illustrating one example of the bonding structure of the first pixel electrode and the first light emitting element and the bonding structure of the second pixel electrode and the second light emitting element of FIGS. 15–16 in detail.

Referring to FIG. 18, the first light emitting element LE1 may be bonded and electrically connected to the first pixel electrode PXE1 by a first connection electrode BE-1 and may be bonded and electrically connected to the common electrode CE by a second connection electrode BE-2.

The second light emitting element LE2 may be bonded and electrically connected to the second pixel electrode PXE2 by the first bottom bonding electrode BBE1 and the first upper bonding electrode UBE1 and may be bonded and electrically connected to the common electrode CE by the second bottom bonding electrode BBE2 and the second upper bonding electrode UBE2.

A height of the first light emitting element LE1 may be different from a height of the second light emitting element LE2. For example, the height h-LE1 of the first light emitting element LE1 may be higher than (e.g., longer than) the height h-LE2 of the second light emitting element LE2. The height h-LE1 of the first light emitting element LE1 is the height from the bottom surface to the top surface of the first light emitting element LE1, where the bottom surface of the first light emitting element LE1 is an interface between the first light emitting element LE1 and the bonding metal pad BMP, and the top surface may be a surface facing the bottom surface (e.g., a surface opposite the bottom surface). The height h-LE2 of the second light emitting element LE2 is the height from the bottom surface to the top surface of the second light emitting element LE2, where the bottom surface of the second light emitting element LE2 is an interface between the second light emitting element LE2 and the upper bonding electrode UBE, and the top surface may be a surface facing the bottom surface (e.g., a surface opposite the bottom surface).

The distance h-S1 from the interface of the first pixel electrode PXE1 and the non-conductive bonding organic pad BOP-1 to the top surface of the first light emitting element LE1 is the same as the distance h-S2 from the interface of the second pixel electrode PXE2 and the bottom bonding electrode BBE to the top surface of the second light emitting element LE2. Therefore, the top surface of the first light emitting element LE1 and the top surface of the second light emitting element LE2 may be arranged on the same plane.

The distance h-S1 from the interface of the first pixel electrode PXE1 and the non-conductive bonding organic pad BOP-1 to the top surface of the first light emitting element LE1 is the sum of the height h-LE1 of the first light emitting element LE1, the height of the bonding metal pad BMP, and the height of the non-conductive bonding organic pad BOP-1 (e.g., a height of a portion of the non-conductive bonding organic pad BOP-1). The height may be a distance in the third direction DR3.

The distance h-S2 from the interface of the second pixel electrode PXE2 and the bottom bonding electrode BBE to the top surface of the second light emitting element LE2 is the sum of the height h-LE2 of the second light emitting element LE2, the height of the bottom bonding electrode BBE, and the height of the upper bonding electrode UBE.

The top surface of the first light emitting element LE1 may be flat because it does not include a light extraction pattern LEP. On the other hand, the top surface of the second light emitting element LE2 may include a light extraction pattern LEP having a semicircular or semi-elliptical cross-sectional shape but is not limited thereto.

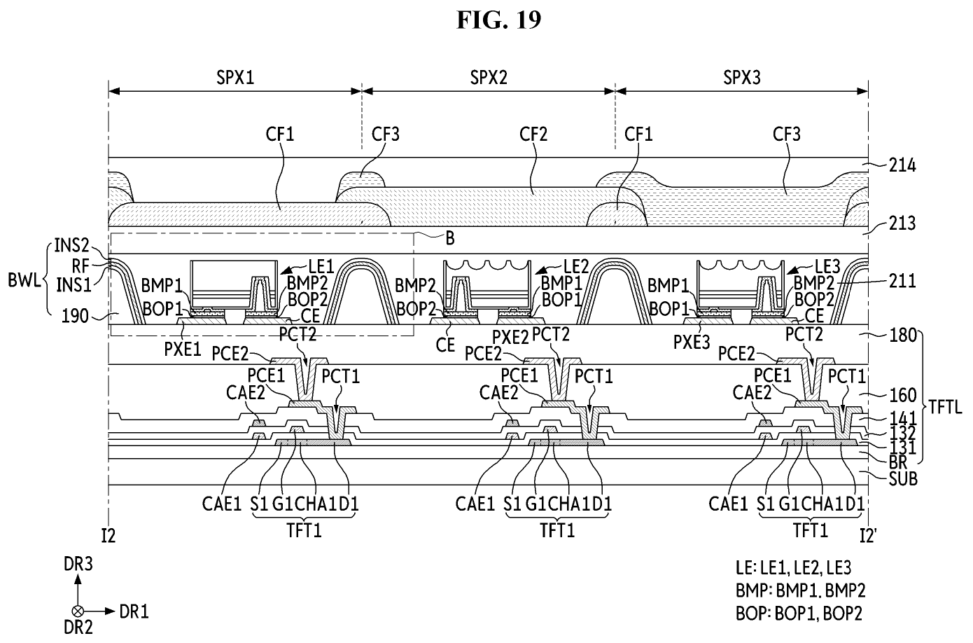

FIG. 19 is a cross-sectional view illustrating one example of a cross-section of a display panel corresponding to the line I2-I2' of FIG. 9 according to on rot more embodiments.

The embodiment of FIG. 19 is different from the embodiment of FIG. 10 in that the light emitting elements LE are bonded by the bonding organic pad BOP and the bonding metal pad BMP in the second sub-pixel SPX2 and the third sub-pixel SPX3. In FIG. 19, overlapping descriptions with the embodiment of FIG. 10 will be omitted, and differences from the embodiment of FIG. 10 will be mainly described.

Referring to FIG. 19, when the same bonding metal pad BMP is arranged on the bottom surfaces of the first light emitting element LE1, the second light emitting element LE2, and the third light emitting element LE3, the same bonding organic pad BOP may be arranged on the bottom surfaces of the bonding metal pads BMP.

The first light emitting element LE1, the second light emitting element LE2, and the third light emitting element LE3 may be electrically connected to the pixel electrode layer by the bonding organic pad BOP and the bonding metal pad BMP.

For example, the first light emitting element LE1 may be bonded and electrically connected to the first pixel electrode PXE1 by a first bonding organic pad BOP1 and a first bonding metal pad BMP1 and may be bonded and electrically connected to the common electrode CE by a second bonding organic pad BOP2 and a second bonding metal pad BMP2. The second light emitting element LE2 may be bonded and electrically connected to the second pixel electrode PXE2 by the first bonding organic pad BOP1 and the first bonding metal pad BMP1 and may be bonded and electrically connected to the common electrode CE by the second bonding organic pad BOP2 and the second bonding metal pad BMP2. The third light emitting element LE3 may be bonded and electrically connected to the third pixel electrode PXE3 by the first bonding organic pad BOP1 and the first bonding metal pad BMP1 and may be bonded and electrically connected to the common electrode CE by the second bonding organic pad BOP2 and the second bonding metal pad BMP2.

In one embodiment of FIG. 19, each of the first bonding organic pads BOP1 and the second bonding organic pads BOP2 may have a different height with respect to the first light emitting element LE1 than the height with respect to the second light emitting element LE2. For example, the distance of the first light emitting element LE1 in the third direction may be longer than the distance of the second light emitting element LE2 in the third direction. In other words, the height of the first light emitting element LE1 may be higher than the height of the second light emitting element LE2. The height of the first light emitting element LE1 is the height from the bottom surface to the top surface of the first light emitting element LE1, where the bottom surface of the first light emitting element LE1 is an interface between the first light emitting element LE1 and the bonding metal pad BMP, and the top surface may be a surface facing the bottom surface (e.g., a surface opposite the bottom surface). The height of the second light emitting element LE2 is the height from the bottom surface to the top surface of the second light emitting element LE2, where the bottom surface of the second light emitting element LE2 is an interface between the second light emitting element LE2 and the bonding metal pad BMP, and the top surface may be a surface facing the bottom surface (e.g., a surface opposite the bottom surface). The height of the second light emitting element LE2 is the same as the height of the third light emitting element LE3. The height of the third light emitting element LE3 is the height from the bottom surface to the top surface of the third light emitting element LE3, where the bottom surface of the third light emitting element LE3 is an interface between the third light emitting element LE3 and the bonding metal pad BMP, and the top surface may be a surface facing the bottom surface (e.g., a surface opposite the bottom surface).

The bonding organic pad BOP is arranged between the pixel electrodes PXE1, PXE2, and PXE3 and the common electrode CE and the light emitting element LE in each sub-pixel and may compensate for the step between the light emitting elements LE as a pseudo-adhesive layer. This is because the lower portion of the longer light emitting element LE sinks into the bonding organic pad BOP, and the bonding organic pad BOP also becomes thinner due to the pressurization.

As shown in FIG. 19, the distance from the interface of the first pixel electrode PXE1 and the bonding organic pad BOP to the top surface of the first light emitting element LE1 is the same as the distance from the interface of the second pixel electrode PXE2 and the bonding organic pad BOP to the top surface of the second light emitting element LE2. The distance from the interface of the second pixel electrode PXE2 and the bonding organic pad BOP to the top surface of the second light emitting element LE2 is the same as the distance from the interface of the third pixel electrode PXE3 and bonding organic pad BOP to the top surface of the third light emitting element LE3. Therefore, the top surface of the first light emitting element LE1, the top surface of the second light emitting element LE2, and the top surface of the third light emitting element LE1 may be arranged on the same plane.

The distance from the interface of the first pixel electrode PXE1 and the bonding organic pad BOP to the top surface of the first light emitting element LE1 is the sum of the height of the first light emitting element LE1, the height of the bonding metal pad BMP, and the height of the bonding organic pad BOP.

As shown in FIG. 19, the distance from the interface of the second pixel electrode PXE2 and bonding organic pad BOP to the top surface of the second light emitting element LE2 is the sum of the height of the second light emitting element LE2, the height of the bonding metal pad BMP, and the height of the bonding organic pad BOP.

As shown in FIG. 19, The distance from the interface of the third pixel electrode PXE3 and the bonding organic pad BOP to the top surface of the third light emitting element LE3 is the sum of the height of the third light emitting element LE3, the height of the bonding metal pad BMP, and the height of the bonding organic pad BOP.

As illustrated in the embodiment of FIG. 19, when the same bonding metal pad BMP is arranged on the bottom surfaces of the first light emitting element LE1, the second light emitting element LE2, and the third light emitting element LE3, the step difference between the first light emitting element LE1, the second light emitting element LE2, and the third light emitting element LE3 may be compensated for by using a bonding organic pad BOP that is pseudo-adhesion and conductive on the bottom surface of the bonding metal pad BMP. When the step difference between the first light emitting element LE1, the second light emitting element LE2, and the third light emitting element LE3 is compensated for, when applying heat and pressure in the bonding process, the same pressure may be applied to the first light emitting element LE1, the second light emitting element LE2, and the third light emitting element LE3, thereby reducing or minimizing defects.

On the other hand, if the upper bonding electrode UBE instead of the bonding metal pad BMP is arranged on one surface of the second light emitting element LE2 and the third light emitting element LE3, the upper bonding electrode UBE may affect the conductivity of the bonding organic pad BOP. Therefore, if the bonding organic pad BOP is arranged under the upper bonding electrode UBE, a separate connection electrode may be additionally required to electrically connect the second light emitting element LE2 and the third light emitting element LE3 and the pixel electrode layer.

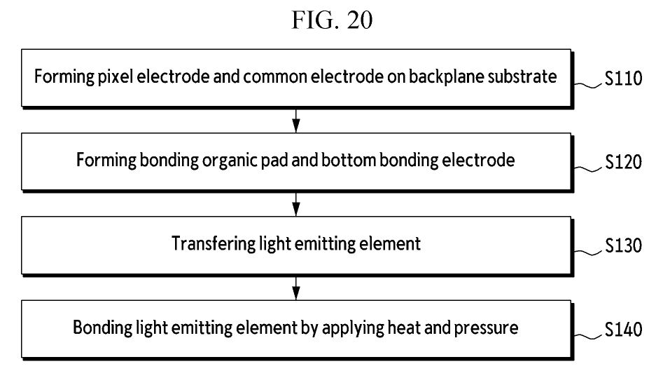

FIG. 20 is a flowchart illustrating a method of manufacturing a display device according to one or more embodiments.

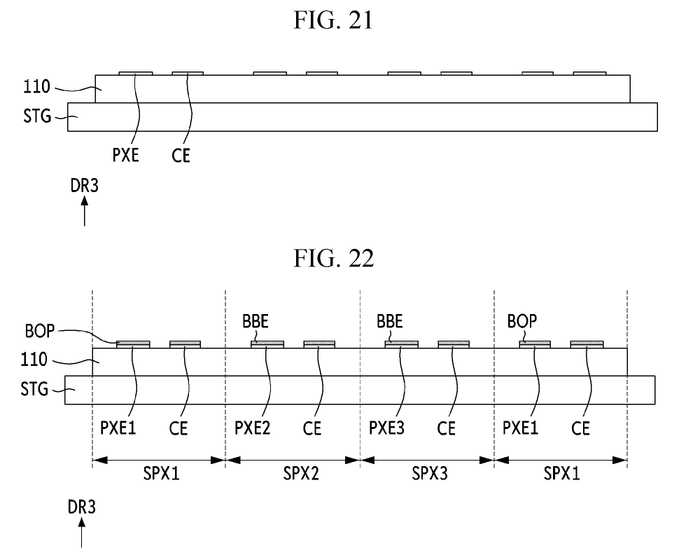

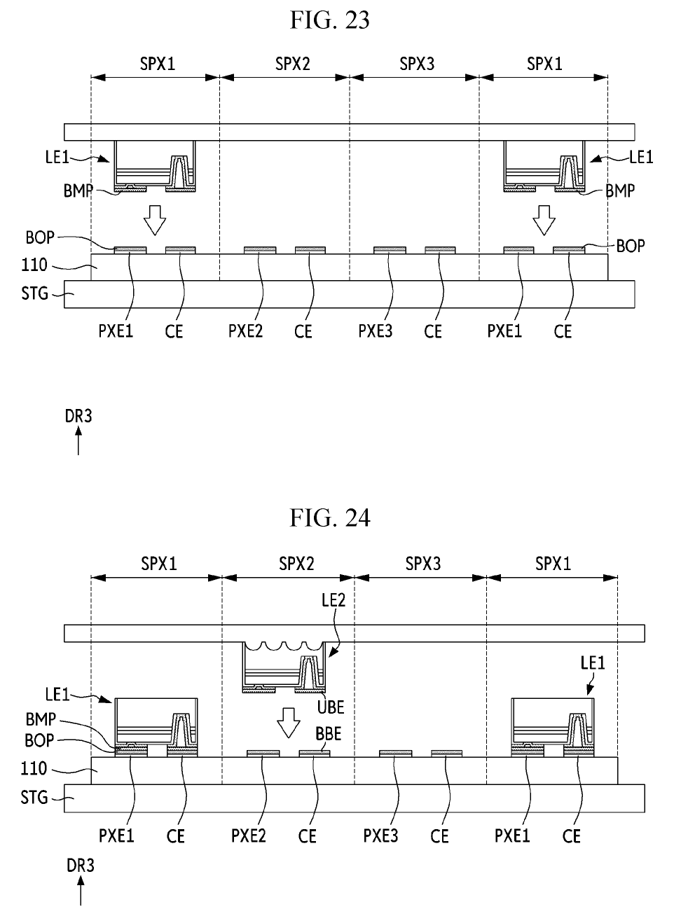

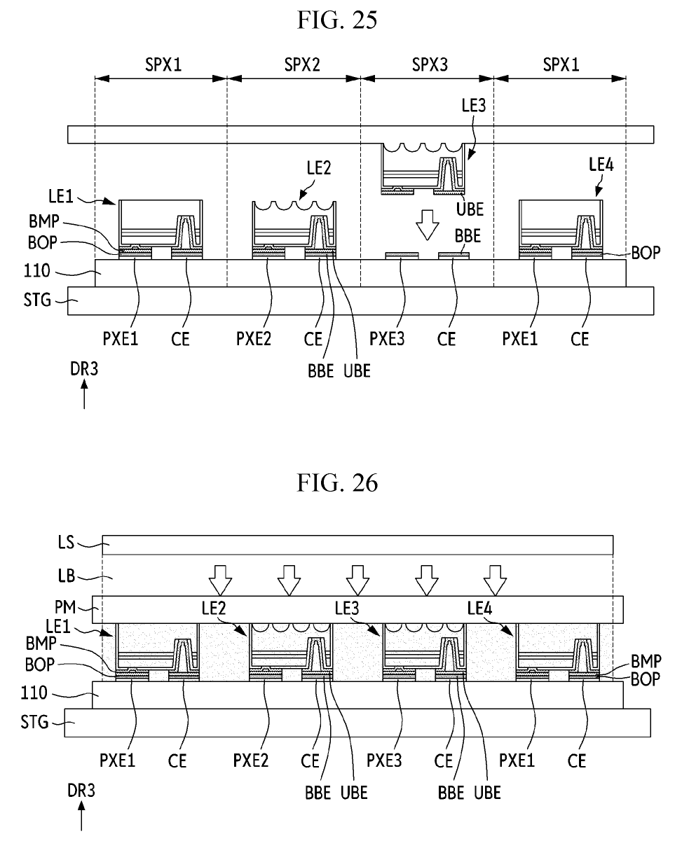

FIGS. 21 – 27 are cross-sectional views illustrating manufacturing steps of a display device according to one or more embodiments. Hereinafter, a method for manufacturing a display device will be described with reference to FIGS. 20 – 27, with reference to FIG. 16.

The method for manufacturing a display device described with reference to FIGS. 20 – 21 with reference to FIG. 20 may be a display device including a light emitting element and a display panel described with reference to FIGS. 10 – 12.

Referring to FIG. 21, pixel electrodes PXE1 and a common electrode CE of a backplane substrate 110 are formed. (S110 in FIG. 20)

For example, an electrode material layer may be formed on the entire surface of the backplane substrate 110 and a photolithography process may be performed to form island-shaped pixel electrodes PXE and the common electrode CE. The photolithography process may include a process of applying a photoresist on the electrode material layer and exposing, developing, and etching the photoresist using a mask.

Here, the backplane substrate 110 may include a substrate SUB described in FIG. 10 and a thin-film transistor layer TFTL.

Referring to FIG. 22, a bonding organic pad BOP and a bottom bonding electrode BBE are formed. (S120 in FIG. 20)

In one or more embodiments, the bonding organic pad BOP is formed on the pixel electrodes PXE1 and the common electrode CE of the first sub-pixel SPX1, the bottom bonding electrode BBE is formed on the pixel electrodes PXE2 and the common electrode CE of the second sub-pixel SPX2, and the bottom bonding electrode BBE is formed on the pixel electrodes PXE3 and the common electrode CE of the third sub-pixel SPX3.

For example, a conductive organic material layer is formed on the entire surface of the backplane substrate 110, and the bonding organic pad BOP is formed on the pixel electrodes PXE1 and the common electrode CE of the first sub-pixel SPX1 by a photolithography process. Then, a bonding metal material layer is formed on the entire surface of the backplane substrate 110, and pixel electrodes PXE2 and the common electrode CE of the second sub-pixel SPX2 and pixel electrodes PXE3 and the common electrode CE of the third sub-pixel SPX3 may be formed by a photolithography process.

Referring to FIGS. 23 – 25, a light emitting element LE is transferred. (S130 in FIG. 20)

In one or more embodiments, a bonding metal pad BMP is arranged on one surface of the first light emitting element LE1. An upper bonding electrode UBE is arranged on one surface of the second light emitting element LE2 and the third light emitting element LE3.

As shown in FIG. 23, the first light emitting element LE1 is arranged on the bonding organic pad BOP of the first sub-pixel SPX1. The bonding metal pad BMP arranged on one side of the first light emitting element LE1 is brought into contact with the bonding organic pad BOP.

As shown in FIG. 24, the second light emitting element LE2 is arranged on the upper bonding electrode UBE of the second sub-pixel SPX2, and the bottom bonding electrode BBE arranged on one side of the second light emitting element LE2 is brought into contact with the upper bonding electrode UBE.

As shown in FIG. 25, the third light emitting element LE3 is arranged on the upper bonding electrode UBE of the third sub-pixel SPX3, and the bottom bonding electrode BBE arranged on one side of the third light emitting element LE3 is brought into contact with the upper bonding electrode UBE.

The heights of the upper portions of the respective light emitting elements LE1, LE2, and LE3 before pressurization may be different.

Referring to FIG. 26, heat and pressure are applied to bond the light emitting element LE. (S140 in FIG. 20)

For example, a pressurizing member PM and a laser LS may be arranged on top of the light emitting element LE.

The pressurizing member PM may be formed of a material that transmits light. For example, the pressurizing member PM may be implemented as one of quartz, sapphire, fused silica glass, and/or diamond. However, in the case of quartz, the laser transmittance is 85% to 99%, which may be preferable.

A laser irradiator LS is arranged on top of the pressurizing member PM, and a laser beam LB is irradiated onto the bonding organic pad BOP and the bonding metal pad BMP of the first sub-pixel SPX1, the upper bonding electrode UBE and the bottom bonding electrode BBE of the second sub-pixel SPX2, and the upper bonding electrode UBE and the bottom bonding electrode BBE of the third sub-pixel SPX3. The laser beam LSB emitted from the laser irradiator LS passes through the pressurizing member PM and is irradiated onto the bonding organic pad BOP and the bonding metal pad BMP of the first sub-pixel SPX1, the upper bonding electrode UBE and the bottom bonding electrode BBE of the second sub-pixel SPX2, and the upper bonding electrode UBE and the bottom bonding electrode BBE of the third sub-pixel SPX3. By irradiating light for about 5 seconds through the laser irradiator LS, the temperature can be raised to 200 to 280 degrees, allowing a bonding process to be performed in a short time. Through the bonding process, the bonding organic pad BOP may be hardened to fix the bonding metal pad BMP arranged on the upper side. Furthermore, the upper bonding electrode UBE and the bottom bonding electrode BBE may be bonded by melting each other.

The bonding organic pad BOP and the bonding metal pad BMP of the first sub-pixel SPX1, the upper bonding electrode UBE and the bottom bonding electrode BBE of the second sub-pixel SPX2, and the upper bonding electrode UBE and the bottom bonding electrode BBE of the third sub-pixel SPX3 are bonded to each other, and ultimately the light emitting element LE is bonded to the backplane substrate 110.

When pressurized, the bonding organic pad BOP is softer than the bottom bonding electrode BBE, so that the first light emitting element LE1 may easily sink into the bonding organic pad BOP, and the bonding organic pad BOP may be thinned by pressurization. Furthermore, the bonding metal pad is fixed by adhesion into the bonding organic pad by pressure, and the bonding organic pad may be cured by heat. The height of the bonding organic pad BOP after the bonding process may be 1 μm or less.

As such, as shown in FIG. 27, the upper portions of each of the light emitting elements LE1, LE2, and LE3 may be arranged on the same layer.

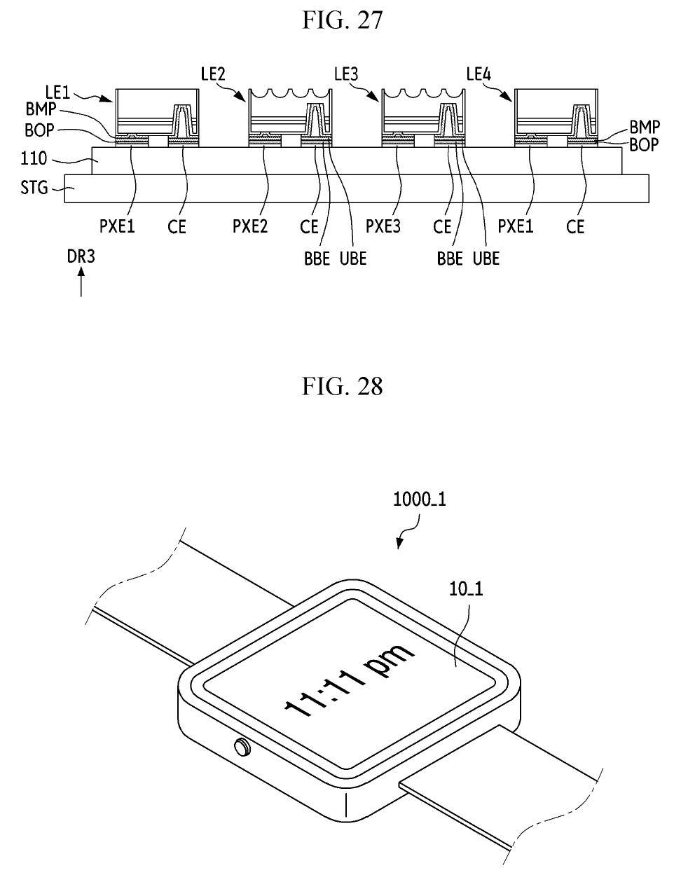

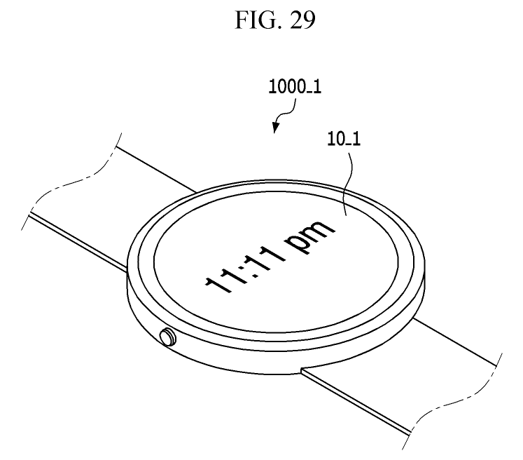

FIGS. 28 and 29 are example drawings illustrating a smart watch including a display device according to one or more embodiments.

Referring to FIGS. 28 and 29, a display device 10_1 according to one or more embodiments may be applied to a smart watch 1000_1, which is one of smart devices.

The flat shape of the display device 10_1 may be a square or a circle but is not limited thereto and may be modified in various ways, such as an oval.

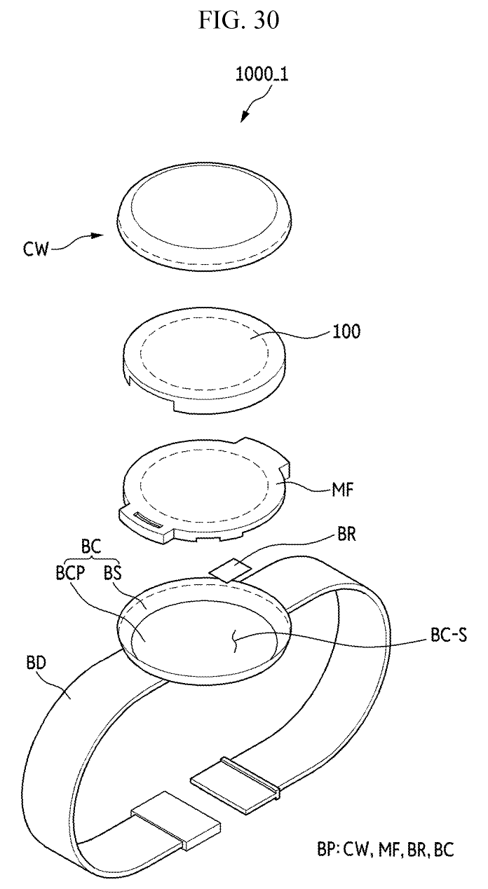

FIG. 30 is an exploded perspective view of a smart watch including a display device according to one or more embodiments.

Referring to FIG. 30, the smart watch 1000_1 may include a main body unit BP and a wearable portion BD.

The main body unit BP may include a display panel 100 on which an image is displayed, a cover window CW disposed on the display panel 100, a bottom cover BC disposed under the display panel 100, a middle frame MF disposed between the cover window CW and the bottom cover BC, and a battery BR disposed between the middle frame MF and the bottom cover BC. In addition to the battery BR, a main processor controlling the smart watch 1000_1, a communication chipset for wirelessly communicating with the outside, and a circuit board in which memory, etc. are mounted may be additionally arranged between the middle frame MF and the bottom cover BC.

The main body unit BP may sequentially include a bottom cover BC, a battery BR, a middle frame MF, a display panel 100, and a cover window CW.

The cover window CW is arranged on the upper portion of the display panel 10 to protect the display panel 10 and to transmit light emitted from the display panel 10. As described above, the cover window CW may include a light-blocking portion to block a portion of the light emitted from the display panel 10. The cover window CW may be made of a transparent plastic material, a glass material, or a reinforced glass material.

The cover window CW may be arranged to overlap the display panel 100 and cover the front of the display panel 100. The cover window CW generally has a shape similar to that of the display panel 100 in terms of a plane, but its size may be larger than that of the display panel 100. For example, the cover window CW may protrude outward from the display panel 100. The plane shape of the cover window CW may be the same as that of the main body unit BP. For example, the planar shape of the cover window CW may be generally circular but is not limited thereto and may have various shapes, for example, a polygon such as a square or an oval.

The middle frame MF is a joining member for joining the cover window CW and the bottom cover BC and is arranged between the cover window CW and the bottom cover BC. For example, the middle frame MF may include a bracket.

The bottom cover BC is a housing arranged under the display panel 10.

The bottom cover BC may include a central cover portion BCP and a peripheral portion BS arranged around the central cover portion BCP.

The central cover portion BCP is located at the center of the bottom cover BC and may be generally flat.

The peripheral portion BS may be arranged to be around (e.g., to surround) the central cover portion BCP. The peripheral portion BS may be a portion that is bent and curved from the central cover portion BCP. The peripheral portion BS may be bent from the edge of the central cover portion BCP. In some embodiments, the peripheral portion BS may include a curved surface having a suitable curvature (e.g., a predetermined curvature), and the other portion may be flat. The degree (or angle) at which the peripheral portion BS is bent from the central cover portion BCP may be an obtuse angle, but is not limited thereto, and may also be a right angle or an acute angle.

A storage space BC-S may be formed by the central cover portion BCP and the peripheral portion BS. A battery BR may be placed in the storage space BC-S.

The battery BR may be connected to a circuit board on which a main processor or the like is mounted. The display device 10_1 may be electrically connected to the circuit board to receive digital video signals, timing signals, power, and/or the like.

The bottom cover BC is placed on the outermost rear surface of the electronic device and may include at least one of a plastic material, a metal material, and a glass material, and may include a color coating layer. For example, the bottom cover BC according to one example may be a flat glass having a transparent, translucent, or opaque color coating layer.

The bottom cover BC according to another example may have the same shape as the cover window CW and may include a glass material having a color coating layer. For example, the bottom cover BC according to another example may have a structure symmetrical to the cover window CW with a middle frame MF in between and may include a transparent, translucent, or opaque color coating layer.

The wearing portion BD is a portion for fixing the main body unit BP to the user's wrist, for example, and may be one of a strap, a chain, and a bracelet.

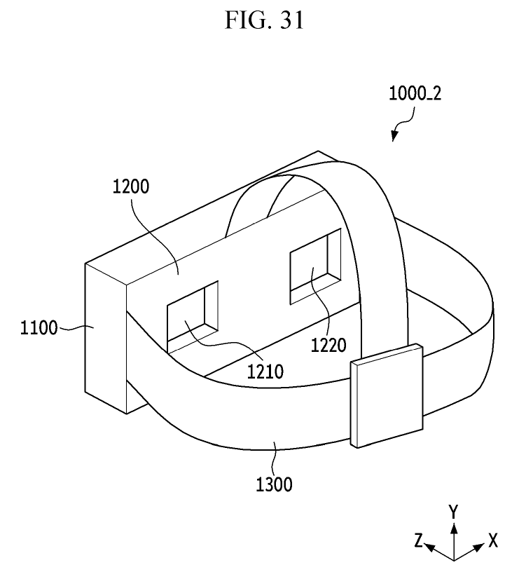

FIG. 31 is example views of a virtual reality (VR) device including a display device according to one or more embodiments.

Referring to FIG. 31, a head mounted display device 1000_2 according to one or more embodiments includes a display device housing 1100, a housing cover 1200, a first eyepiece 1210, a second eyepiece 1220, and head mounted band 1300.

The display device housing 1100 houses a display device. A head mounted display device 1000_b according to one or more embodiments further include a first optical member disposed between the first display device and the first eyepiece 1210.

The housing cover 1200 is placed to cover an open surface of the display device housing 1100. The housing cover 1200 may include the first eyepiece 1210 on which a user’s left eye is placed and the second eyepiece 1220 on which the user’s right eye is placed. Although the first eyepiece 1210 and the second eyepiece 1220 are disposed separately in FIG. 31, the present disclosure is not limited thereto. The first eyepiece 1210 and the second eyepiece 1220 may also be combined into one.

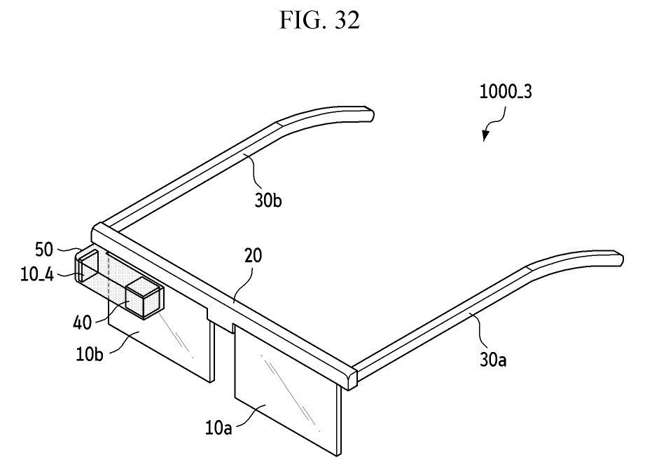

The head mounted band 1300 fixes the display device housing 1100 to a user’s head so that the first eyepiece 1210 and the second eyepiece 1220 of the housing cover 1200 are kept placed on the user’s left and right eyes, respectively. When the display device housing 1200 is implemented to be lightweight and small, the head mounted display device 1000_2 may include an eyeglass frame as illustrated in FIG. 32 instead of the head mounted band 1300.

The display device housing 1100 houses display device. In addition, the head mounted display device 1000_2 may further include a battery for supplying power, an external memory slot for accommodating an external memory, and an external connection port and a wireless communication module for receiving an image source. The external connection port may be a universe serial bus (USB) terminal, a display port, or a high-definition multimedia interface (HDMI) terminal, and the wireless communication module may be a 5G communication module, a 4G communication module, a Wi-Fi module, and/or a Bluetooth module.

FIG. 32 is an example view of a VR device including a display device according to one or more embodiments. FIG. 32 illustrates a VR device 1000_3 to which a display device 10_4 according to one or more embodiments has been applied.

Referring to FIG. 32, the VR device 1000_3 according to one or more embodiments may be a device in the form of glasses. The VR device 1000_3 according to the embodiment may include the display device 10_4, a left lens 10a, a right lens 10b, a support frame 20, eyeglass frame legs 30a and 30b, a reflective member 40, and a display device housing 50.

In FIG. 32, a case where the VR device 1000_3 is a glasses-type display device including the eyeglass frame legs 30a and 30b is illustrated as an example. That is, the VR device 1000_3 according to the embodiment is not limited to the one illustrated in FIG. 32 and can be applied in various forms to various other electronic devices.

The display device housing 50 may include the display device 10_4 and the reflective member 40. An image displayed on the display device 10_4 may be reflected by the reflective member 40 and provided to a user’s right eye through the right lens 10b. Accordingly, the user may view a VR image displayed on the display device 10_4 through the right eye.

Although the display device housing 50 is disposed at a right end of the support frame 20 in FIG. 32, the present disclosure is not limited thereto. For example, the display device housing 50 may also be disposed at a left end of the support frame 20. In this case, an image displayed on the display device 10_4 may be reflected by the reflective member 40 and provided to the user’s left eye through the left lens 10a. Accordingly, the user may view a VR image displayed on the display device 10_4 through the left eye. Alternatively, the display device housing 50 may be disposed at both the right end and the left end of the support frame 20. In this case, the user may view a VR image displayed on the display device 10_4 through both the left eye and the right eye.

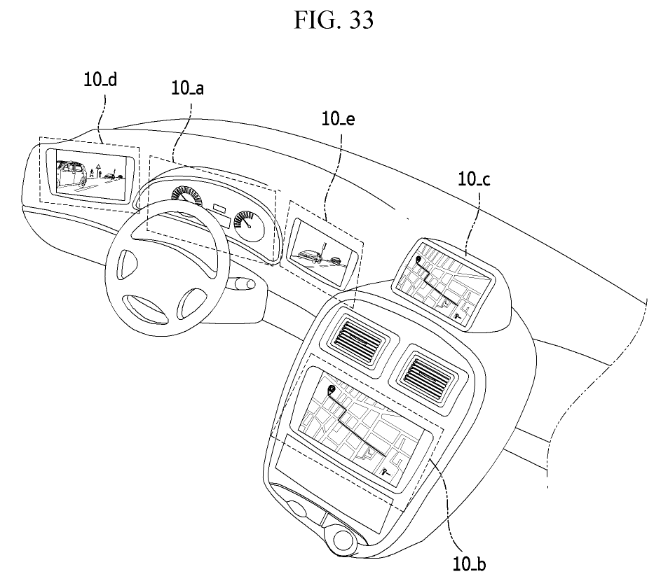

FIG. 33 is an example view illustrating a vehicle instrument cluster and center fascia including display devices according to one or more embodiments. FIG. 33 illustrates a vehicle to which display devices 10_a through 10_e according to one or more embodiments have been applied.

Referring to FIG. 33, the display devices 10_a through 10_c according to the embodiment may be applied to an instrument cluster of the vehicle, a center fascia of the vehicle, or a center information display (CID) disposed on a dashboard of the vehicle. In addition, the display devices 10_d and 10_e according to the embodiment may be applied to room mirror displays that replace side mirrors of the vehicle.

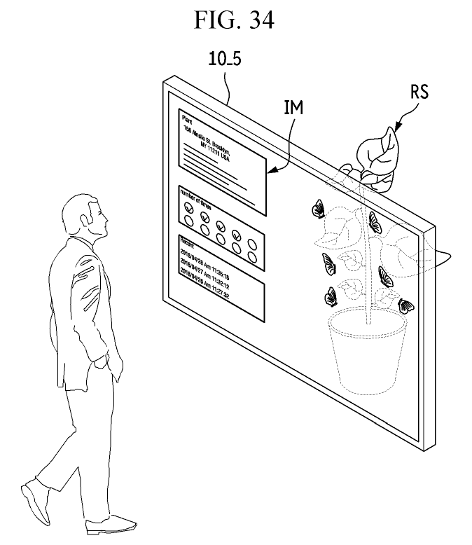

FIG. 34 is an example view of a transparent display device including a display device according to one or more embodiments.

Referring to FIG. 34, a display device 10_5 according to one or more embodiments may be applied to a transparent display device. The transparent display device may transmit light while displaying an image IM. Therefore, a user located in front of the transparent display device cannot only view the image IM displayed on the display device 10_5 but also view an object RS or the background located behind the transparent display device. When the display device 10_5 is applied to the transparent display device, a substrate of the display device 10_5 may include a light transmitting portion that can transmit light or may be made of a material that can transmit light.

It should be understood, however, that the aspects and features of embodiments of the present disclosure are not restricted to the one set forth herein. The above and other aspects of the present disclosure will become more apparent to one of ordinary skill in the art to which the present disclosure pertains by referencing the claims, with equivalents thereof to be included therein.

What is claimed is:

1. A display device comprising:
a substrate including first light emitting areas and second light emitting areas;
first pixel electrodes arranged in the first light emitting areas on the substrate, and second pixel electrodes arranged in the second light emitting areas on the substrate;
first light emitting elements arranged in the first pixel electrodes and configured to emit light of a first wavelength, and second light emitting elements arranged in the second pixel electrodes and configured to emit light of a second wavelength, wherein the second wavelength is a different wavelength than the first wavelength; and
bonding organic pads respectively arranged between the first pixel electrodes and the first light emitting elements corresponding to the first pixel electrodes, and bottom bonding electrodes respectively arranged between the second pixel electrodes and the second light emitting elements corresponding to the second pixel electrodes,
wherein the bonding organic pads and the bottom bonding electrodes comprise different materials,
wherein heights of the first light emitting elements are different from heights of the second light emitting elements,
wherein a distance from an interface of the first pixel electrode and the bonding organic pad to a top surface of the first light emitting element is the same as a distance from an interface of the second pixel electrode and the bottom bonding electrode to a top surface of the second light emitting element.

2. The display device of claim 1, further comprising:
a bonding metal pad arranged between the bonding organic pad and the first light emitting element, and
an upper bonding electrode arranged between the bottom bonding electrode and the second light emitting element.

3. The display device of claim 1, wherein the bonding organic pad comprises an organic material,
wherein the bottom bonding electrode comprises a metal material.

4. The display device of claim 3, wherein the bonding organic pad comprises a polymer resin and conductive nanoparticles dispersed in the polymer resin.

5. The display device of claim 4, wherein the conductive nanoparticles comprise conductive carbon black.

6. The display device of claim 2, wherein the bonding metal pad and the upper bonding electrode comprise different metals.

7. The display device of claim 6, wherein the bonding metal pad comprises a metal having higher conductivity than the upper bonding electrode.

8. The display device of claim 1, wherein a distance from one side of the bonding organic pad to an other side of the bonding organic pad is shorter than a distance from one side of the bottom bonding electrode to an other side of the bottom bonding electrode, and
wherein a distance from one side of the first light emitting element to an other side of the first light emitting element is longer than a distance from one side of the second light emitting element to an other side of the second light emitting element.

9. The display device of claim 8, wherein the distance from the one side of the bonding organic pad to the other side of the bonding organic pad is 1μm or less.

10. The display device of claim 1, wherein the first light emitting elements comprise a gallium arsenide (GaAs) based inorganic material, and the second light emitting elements comprise a gallium nitride (GaN) based material.

11. The display device of claim 10, wherein the first light emitting elements comprise a flat upper portion, and the second light emitting elements comprise an upper portion having a concave structure having a cross-sectional shape of a semicircle or a semiellipse.

12. The display device of claim 10, wherein the first light emitting elements comprise an upper portion having a first concave structure having a cross-sectional shape of a semicircle or a semiellipse, and
wherein the second light emitting elements comprise an upper portion having a second concave structure having a cross-sectional shape of a semicircle or a semiellipse.

13. The display device of claim 12, wherein the first concave structure has a relatively smaller height difference than the second concave structure.

14. The display device of claim 10, wherein each of the first light emitting element and the second light emitting element comprises:
a first semiconductor layer doped with a first conductive dopant;
a second semiconductor layer doped with a second conductive dopant;
an active layer arranged between the first semiconductor layer and the second semiconductor layer;
a protective film arranged on side surfaces of the first semiconductor layer, the active layer, and the second semiconductor layer; and
a contact electrode arranged on a bottom surface of the first semiconductor layer.

15. The display device of claim 3, wherein the bonding organic pads comprise a non-conductive organic material and the first light emitting element further comprises a connection electrode arranged on the first pixel electrode and electrically connecting the first light emitting element.

16. A method for manufacturing a display device comprising:
forming first pixel electrodes in a first light emitting area on a substrate, and second pixel electrodes in a second light emitting area on the substrate;
forming bonding organic pads on the first pixel electrodes and bottom bonding electrodes on the second pixel electrodes using different materials;
arranging first light emitting elements configured to emit light of a first wavelength and have a bonding metal pad arranged on one surface of the first light emitting elements on the bonding organic pads, and arranging second light emitting elements configured to emit light of a second wavelength and have an upper bonding electrode arranged on one surface of the second light emitting elements on the bottom bonding electrode, wherein the second wavelength is a different wavelength from the first wavelength, and heights of the first light emitting elements are different from heights of the second light emitting elements; and
applying pressure from above the first light emitting elements and the second light emitting elements, and applying heat to the bonding organic pads and the bottom bonding electrode to bond the first light emitting elements and the second light emitting elements to the first pixel electrodes and the second pixel electrodes,
wherein a distance from an interface of the first pixel electrode and the bonding organic pad after the pressure to a top surface of the first light emitting element is the same as a distance from an interface of the second pixel electrode and the bottom bonding electrode to a top surface of the second light emitting element.

17. The method of claim 16, wherein based on the applying the pressure from above the first light emitting elements and the second light emitting elements, the bonding metal pad is sunk into the bonding organic pad and fixed by adhesion.

18. The method of claim 16, wherein the bonding organic pad comprises a polymer resin and conductive nanoparticles dispersed in the polymer resin, and
wherein the bottom bonding electrode comprises a metal material.

19. An electronic device comprising:
a display panel;
a window arranged on the display panel; and
a bottom cover arranged below the display panel,
wherein the display panel comprising,
a substrate including first light emitting areas and second light emitting areas;
first pixel electrodes arranged in the first light emitting areas on the substrate, and second pixel electrodes arranged in the second light emitting areas on the substrate;
first light emitting elements arranged in the first pixel electrodes and configured to emit light of a first wavelength, and second light emitting elements arranged in the second pixel electrodes and configured to emit light of a second wavelength, wherein the second wavelength is a different wavelength than the first wavelength; and
bonding organic pads respectively arranged between the first pixel electrodes and the first light emitting elements corresponding to the first pixel electrodes, and bottom bonding electrodes respectively arranged between the second pixel electrodes and the second light emitting elements corresponding to the second pixel electrodes,
wherein the bonding organic pads and the bottom bonding electrodes comprise different materials,
wherein heights of the first light emitting elements are different from heights of the second light emitting elements,
wherein a distance from an interface of the first pixel electrode and the bonding organic pad to a top surface of the first light emitting element is the same as a distance from an interface of the second pixel electrode and the bottom bonding electrode to a top surface of the second light emitting element.

20. The electronic device of claim 19, further comprising:
a battery arranged in a space of the bottom cover and configured to supply power to the display panel; and
a middle frame arranged between the window and the bottom cover.
